(19) United States
(12) Patent Application Publication
(10) Pub. No.: US 2017/0222162 A1
(43) Pub. Date: Aug. 3, 2017

(54) METAL HALIDE PEROVSKITE LIGHT EMITTING DEVICE AND METHOD OF MANUFACTURING THE SAME

(71) Applicant: POSTECH ACADEMY - INDUSTRY FOUNDATION, Pohang (KR)

(72) Inventors: Tae-Woo LEE, Pohang (KR); Su-Hun JEONG, Busan (KR)

(21) Appl. No.: 15/372,567

(22) Filed: Dec. 8, 2016

(30) Foreign Application Priority Data
Jan. 28, 2016 (KR) 10-2016-0010807

(51) Int. Cl. H01L 51/00

(52) U.S. Cl. CPC H01L 51/0077; H01L 51/0037; H01L 51/0035; H01L 51/0034; H01L 51/5012

(57) ABSTRACT

Provided are a metal halide perovskite light emitting device and a method of manufacturing the same. The metal halide perovskite light emitting device includes a substrate, a first electrode formed on the substrate, a light emitting layer formed on the first electrode and including a metal halide perovskite material, and a second electrode disposed on the light emitting layer, the first electrode includes a conductive layer and a surface energy-tuning layer disposed on the conductive layer, the conductive layer includes a conductive polymer and a first fluorine-based material, and the surface energy-tuning layer includes a second fluorine-based material but does not include the conductive polymer. Therefore, the first electrode can come in ohmic contact with a metal halide perovskite light emitting layer by adjusting a work function, and can prevent the dissociation of excitons to enhance luminous efficiency, thereby effectively improving efficiency of a light emitting device.

### CLAIM FOR PRIORITY

This application claims priority to Korean Patent Application No. 10-2016-0010807 filed on Jan. 28, 2016 in the Korean Intellectual Property Office (KIPO), the entire contents of which are hereby incorporated by reference.

### BACKGROUND

1. Technical Field

Example embodiments of the present invention relate in general to a metal halide perovskite light emitting device and a method of manufacturing the same, and more particularly, to a metal halide perovskite light emitting device having improved luminous efficiency, and a method of manufacturing the same.

2. Related Art

In recent years, the display industry has been changed from inorganic light emitting diodes (LEDs) to organic light emitting diodes. The organic light emitting diodes have characteristics such as a relatively simple and lightweight structure and processability as well as a flexible characteristic, and thus have come into the spotlight as next-generation flexible electronic devices. Meanwhile, following the organic light emitting diodes, inorganic quantum dot materials have come into the spotlight due to their advantages such as high color purity.

However, the organic light emitting diodes have high efficiency, but have a drawback in that the color purity may be deteriorated due to a wide full width at half maximum of an emission spectrum, and the inorganic quantum dots in which color is adjusted according to the size of the quantum dots have high color purity, but have a drawback in that it is very difficult to adjust the size of the quantum dot during a synthesis process. Also, the organic light emitting diodes and the inorganic quantum dot materials have a limitation in manufacturing low-priced products due to high manufacturing costs. Therefore, research on perovskite light emitting diodes which exhibit high color purity, are manufactured by a simple process and have a low manufacturing cost is needed.

In particular, metal halide perovskite materials have advantages in that they have a low unit price, are synthesized by a very simple method, and can be subjected to a solution process. Also, the metal halide perovskite materials have photoluminescence and electroluminescence characteristics, and thus can be applied to light emitting diodes.

Metal halide perovskite has an ABX₃ structure, and is in the form of a combination of face-centered cubic (FCC) and body-centered cubic (BCC) structures. Halogen elements such as Cl, Br and I are positioned on X sites, organic ammonium (RNH₃) cations or monovalent alkali metal ions are positioned on A sites, and metal elements (alkali metals, alkali earth metals, transition metals, etc.) such as Pb, Mn, Cu, Ge, Sn, Ni, Co, Fe, Cr, Pd, Cd, or Yb are positioned on B sites.

The metal halide perovskite may have a structure of A₂BX₄, ABX₄ or Aₙ₋₁PbₙI₃ₙ₊₁ (n is an integer ranging from 2 to 6), all of which have a lamellar-type two-dimensional (2D) structure.

Here, A is an organic ammonium material, B is a metal material, and X is a halogen element. For example, A may be (CH₃NH₃)ₙ, ((CₓH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂ or (CₙF₂ₙ₊₁NH₃)₂ (n is an integer greater than or equal to 1, and x is an integer greater than or equal to 1), and B may be a divalent transition metal, a rare earth metal, an alkaline earth metal, Pb, Sn, Ge, Ga, In, Al, Sb, Bi, Po, or a combination thereof. In this case, the rare earth metal may, for example, be Ge, Sn, Pb, Eu, or Yb. Also, the alkaline earth metal may, for example, be Ca or Sr. In addition, X may be Cl, Br, I, or a combination thereof.

As such, the metal halide perovskite includes an organic metal halide perovskite having an organic substance on the A site. The organic metal halide perovskite is similar to an inorganic metal oxide having a perovskite structure (ABX₃) in that both of them have a perovskite crystal structure, but actually has quite different compositions and characteristics from the inorganic metal oxide. The inorganic metal oxide is generally an oxide which does not include a halide, that is, a material in which metal (alkali metal, alkali earth metal, transition metal, and lanthanide) cations having different sizes, such as Ti, Sr, Ca, Cs, Ba, Y, Gd, La, Fe, Mn, etc., are positioned on the A and B sites, and the metal cations on the B site are bound to O (oxygen) anions in the form of a corner-sharing octahedron with 6-fold coordination. Examples of the inorganic metal oxide include SrFeO₃, LaMnO₃, CaFeO₃, etc. On the other hand, the organic metal halide perovskite has a structure in which organic ammonium (RNH₃) cations are positioned on the A site and halides (Cl, Br, and I) are positioned on the X site, and thus has quite different compositions from the inorganic metal oxide. The characteristics of materials differ, depending on a difference in such components. The inorganic metal oxide typically has characteristics such as superconductivity, ferroelectricity, colossal magnetoresistance, etc., and thus generally has been studied to be applicable to sensors, fuel cells, memory devices, etc. By way of an example, yttrium barium copper oxide has either a superconducting or insulating property, depending on oxygen content.

On the other hand, since the organic metal halide perovskite has a lamellar structure in which organic and inorganic planes are alternately stacked, and enables excitons to be trapped in the inorganic plane, the organic metal halide perovskite may be essentially an ideal phosphor that emits light having very high color purity, depending on the crystal structure itself rather than the size of the material.

Even in the case of the organic metal halide perovskite, when the organic ammonium includes a core metal and a chromophore having a smaller band gap than a halogen crystal structure (BX₃), the light emission is generated in the organic ammonium. As a result, since the organic ammonium does not emit light of high color purity (a full width at half maximum of less than 30 nm), the full width at half maximum of an emission spectrum should become wider than 50 nm, which makes the organic ammonium unsuitable for light emitting layers. Therefore, in this case, the organic ammonium is very unsuitable for phosphors having high color purity (a full width at half maximum of less than 30 nm) emphasized in this patent application. Accordingly, it is important that the organic ammonium does not include a chromophore and the light emission occurs in an inorganic lattice composed of a core metal and a halogen element so as to prepare a phosphor having high color purity. This is because the band gap, the valence band maximum and the conducting band minimum of the material does not depend on an organic ligand, and depends on the core metal and halide atoms. Therefore, this patent application has focused on development of phosphors of high color purity and efficiency in which the light emission occurs in the inorganic lattice.

Although such a metal halide perovskite has advantages as the light emitting diode, the metal halide perovskite has a problem of limited application to light emitting diodes.

First, a problem such as a decline in efficiency of a light emitting diode is caused due to various types of defects present inside perovskites. Since a point-defect-type trap and a linear grain boundary are formed to enable electrons and holes to thermally induce non-radiative recombination, efficiency may be reduced in both the solar cell and the light emitting diode. That is, since such defects exist out of an energy level of a conduction band or a valence band, the electrons or holes are trapped at an energy level of the defects to limit movement of charges and induce unwanted non-radiative recombination.

Second, an exciton recombination rate is determined by the size of grains. That is, as the size of grains in perovskites decreases, a diffusion length of charges decreases, and a quantity of the charges present in the grains increases, resulting in an increased recombination rate. Therefore, it is important to effectively reduce the size of the grains, compared to those in the art.

Third, metal halide perovskite materials are known to have p-type characteristics. In particular, the metal halide perovskite materials have been reported as materials which are not thermodynamically converted into the n-type when Br is used, and thus are known to exhibit p-type characteristics. In the light emitting diodes in which the balance between the electrons and the holes is important, the perovskites having the p-type characteristics have a problem in that they have no option but to exhibit low efficiency.

Fourth, metal halide perovskite thin films often prepared for conventional solar cells are known to have a low exciton binding energy (<50 nm) and a very long exciton diffusion length (>100 nm). However, an increase in the exciton binding energy and a decrease in the exciton diffusion length should be achieved to enhance luminous efficiency. In this way, the metal halide perovskite thin film has a drawback in that it is difficult to implement using a thin film manufacturing process (in which a device having higher efficiency has a higher grain size (>200 nm) and a severe surface unevenness) used in metal halide solar cells known in the art.

Fifth, since transparent metal oxide electrodes of a metal halide perovskite light emitting device have a property of being easily broken due to instability when the transparent metal oxide electrodes are bent, they are difficult to apply to flexible metal halide perovskite light emitting devices. Therefore, there is a need for development of transparent flexible electrodes which can replace the transparent metal oxide electrodes.

### PRIOR-ART DOCUMENTS

### Patent Documents

Korean Patent Unexamined Publication No. 10-2014-0009939

### SUMMARY

Accordingly, example embodiments of the present invention are provided to substantially obviate one or more problems due to limitations and disadvantages of the related art.

Example embodiments of the present invention provide a metal halide perovskite light emitting device capable of preventing dissociation of excitons at the interface between a metal halide perovskite light emitting layer and electrodes and coming in ohmic contact with the metal halide perovskite light emitting layer, and a method of manufacturing the same.

In an aspect of the present invention, a metal halide perovskite light emitting device is provided. The metal halide perovskite light emitting device includes a substrate, a first electrode disposed on the substrate, a light emitting layer disposed on the first electrode and including a metal halide perovskite material, and a second electrode disposed on the light emitting layer. Here, the first electrode includes a conductive layer, and a surface energy-tuning layer disposed on the conductive layer, the conductive layer includes a conductive polymer and a first fluorine-based material, and the surface energy-tuning layer includes a second fluorine-based material, but does not include the conductive polymer.

In this case, the first fluorine-based material and the second fluorine-based material may be the same or different from each other.

Also, the first electrode may further include an interlayer disposed between the conductive layer and the surface energy-tuning layer. In this case, the interlayer may include the first fluorine-based material and the second fluorine-based material, and the first fluorine-based material and the second fluorine-based material may be different from each other.

In another aspect of the present invention, a method of manufacturing a metal halide perovskite light emitting device is provided. The method of manufacturing a metal halide perovskite light emitting device includes forming a first electrode on a substrate, forming a light emitting layer including a metal halide perovskite material on the first electrode, and forming a second electrode on the light emitting layer. Here, the first electrode includes a conductive layer and a surface energy-tuning layer disposed on the conductive layer, the conductive layer includes a conductive polymer and a first fluorine-based material, and the surface energy-tuning layer includes a second fluorine-based material but does not include the conductive polymer.

Also, the forming of the first electrode may include providing a first mixture, which includes a conductive polymer, a first fluorine-based material, and a first solvent, onto the substrate and then removing at least a portion of the first solvent to form a conductive layer, and providing a second mixture, which includes a second fluorine-based material and a second solvent, onto the conductive layer and then removing at least a portion of the second solvent to form a surface energy-tuning layer.

In addition, the first electrode may further include an interlayer disposed between the conductive layer and the surface energy-tuning layer, the interlayer may include the first fluorine-based material and the second fluorine-based material, and the first fluorine-based material and the second fluorine-based material may be different from each other.

Additionally, the forming of the first electrode may further include providing a first mixture, which includes a conductive polymer, a first fluorine-based material, and a first solvent, onto the substrate and then removing at least a portion of the first solvent to form a conductive layer, and providing a second mixture, which includes a second fluorine-based material and a second solvent, onto the conductive layer and then removing at least a portion of the second solvent to form an interlayer and a surface energy-tuning layer at the same time.

Further, a first layer including the conductive polymer, the first fluorine-based material, the second fluorine-based material, and the second solvent may be formed, and a second layer including the second fluorine-based material and the second solvent may be formed on the first layer when the second mixture is provided onto the conductive layer, and the interlayer comprising the conductive polymer, the first fluorine-based material, and the second fluorine-based material, and the surface energy-tuning layer including the second fluorine-based material but not including the conductive polymer are formed at the same time by removing the second solvent.

### BRIEF DESCRIPTION OF DRAWINGS

Example embodiments of the present invention will become more apparent by describing in detail example embodiments of the present invention with reference to the accompanying drawings, in which:

FIG. 1 is a schematic cross-sectional view of a first electrode according to one exemplary embodiment of the present invention;

FIG. 2 is a schematic cross-sectional view of a first electrode according to another exemplary embodiment of the present invention;

FIG. 3 is a schematic cross-sectional view of a metal halide perovskite light emitting device according to one exemplary embodiment of the present invention; and

FIG. 4 is a graph illustrating luminous efficiency characteristics of the metal halide perovskite light emitting device according to one exemplary embodiment of the present invention.

### DESCRIPTION OF EXAMPLE EMBODIMENTS

Example embodiments of the present invention are disclosed herein. However, specific structural and functional details disclosed herein are merely representative for purposes of describing example embodiments of the present invention, and example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/actions noted in the blocks may occur out of the order noted in the flowcharts. For example, two blocks shown in succession may in fact be executed substantially concurrently or the blocks may sometimes be executed in the reverse order, depending upon the functionality/actions involved.

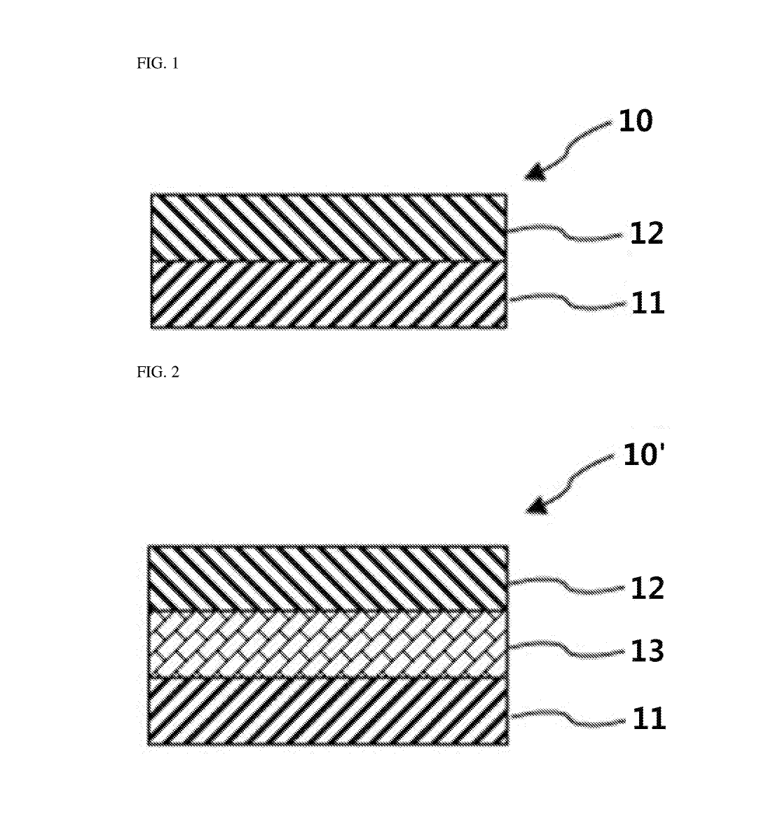

FIG. 1 is a schematic cross-sectional view of a first electrode according to one exemplary embodiment of the present invention.

Referring to FIG. 1, the first electrode 10 may include a conductive layer 11 and a surface energy-tuning layer 12.

The conductive layer 11 may include a conductive polymer and a first fluorine-based material.

The surface energy-tuning layer 12 is disposed on the conductive layer 11. The surface energy-tuning layer 12 includes a second fluorine-based material, but does not include a conductive polymer included in the conductive layer 11.

In this case, the first fluorine-based material and the second fluorine-based material may be the same or different from each other.

The conductive polymer in the conductive layer 11 may, for example, include polythiophene, polyaniline, polypyrrole, polystyrene, polyethylenedioxythiophene, polyacetylene, polyphenylene, polyphenylvinylene, polycarbazole, a copolymer including two or more different repeating units thereof, a derivative thereof, or a blend of two or more types thereof.

The “copolymer” includes a copolymer in which all the different repeating units of the conductive polymers are included in the main chain thereof, a graft-type copolymer in which one of the different repeating units of the conductive polymers is included in a side chain thereof, etc. Also, the “copolymer” may be a random copolymer, an alternative copolymer, or a block copolymer.

The “derivative” may include a conductive polymer having an ionic group bound thereto, a conductive polymer bound to a polymeric acid containing an ionic group via the ionic group (for example, via an ionic bond), etc.

Therefore, the conductive polymer may include a self-doped conductive polymer doped with one or more types of an ionic group, and a polymer.

The ionic group may include an anionic group, and a cationic group disposed to counter the anionic group.

For example, the anionic group may be selected from the group consisting of PO₃²⁻, SO₃⁻, COO⁻, I⁻, CH₃COO⁻, and BO₂²⁻.

Meanwhile, the cationic group may include one or more types among a metal ion and an organic ion.

For example, the metal ion may be selected from the group consisting of Na⁺, K⁺, Li⁺, Mg⁺², Zn⁺², and Al⁺³, and the organic ion may be selected from the group consisting of H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, and RCHO⁺ (R is CH₃(CH₂)ₙ—; and n is an integer ranging from 0 to 50), but the present invention is not limited thereto.

The polymeric acid may be a conductive polymer in which the ionic group as described above is bound to a side chain thereof. In this case, the conductive polymer may be readily recognized from polymers 1 to 25 to be described below.

For example, specific examples of the conductive polymer are as described below, but the present invention is not limited thereto:

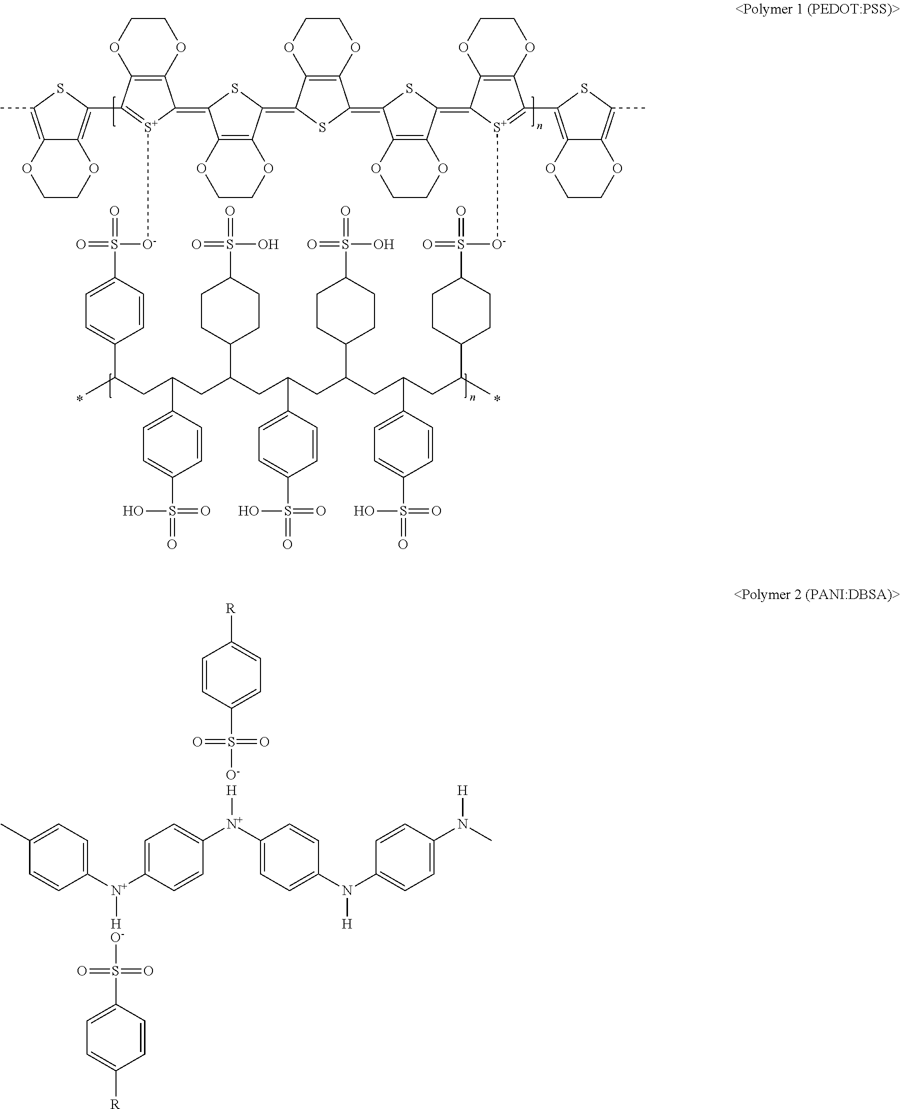

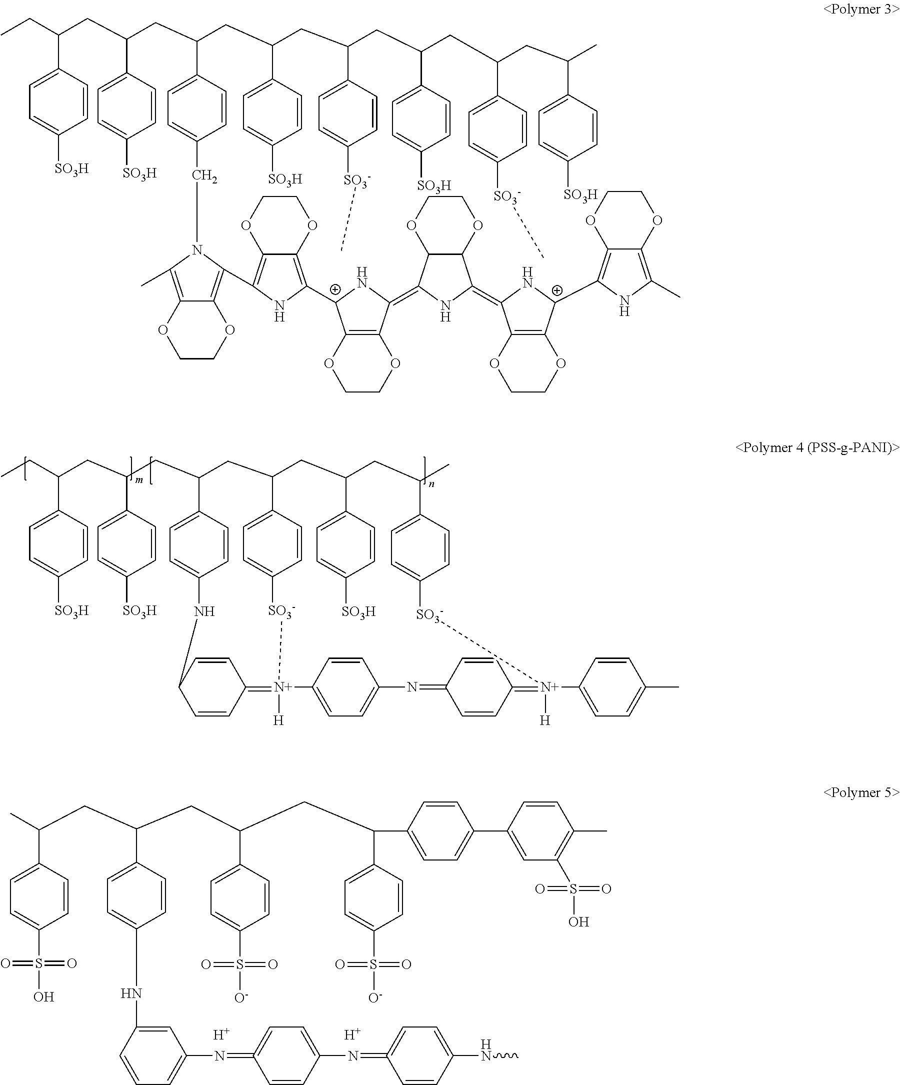

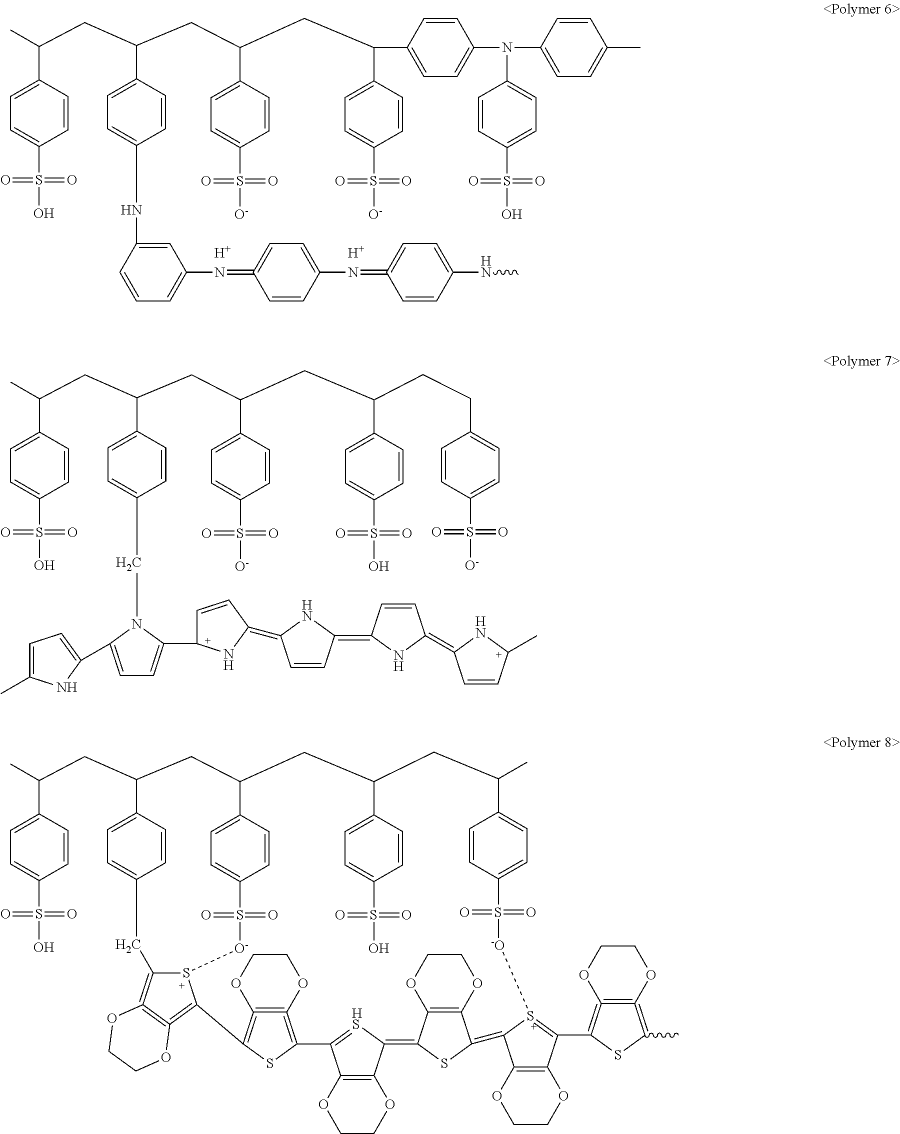

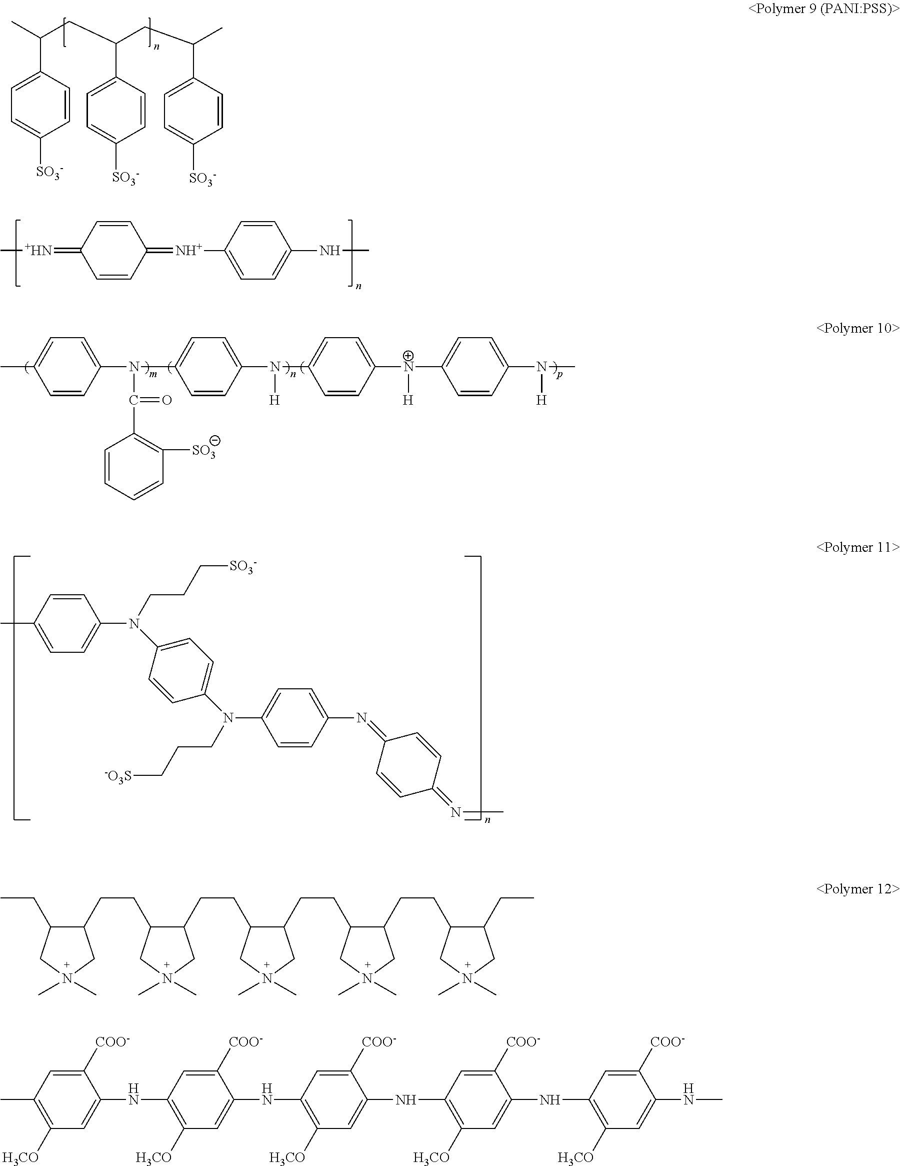

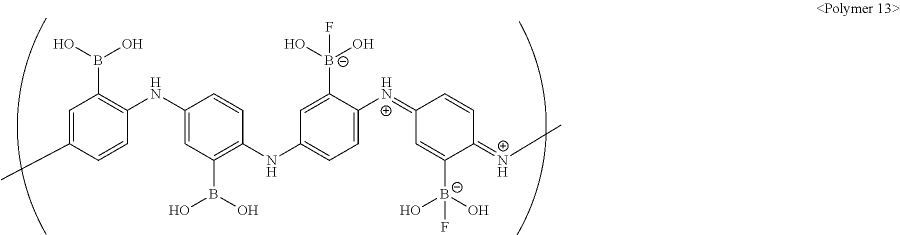

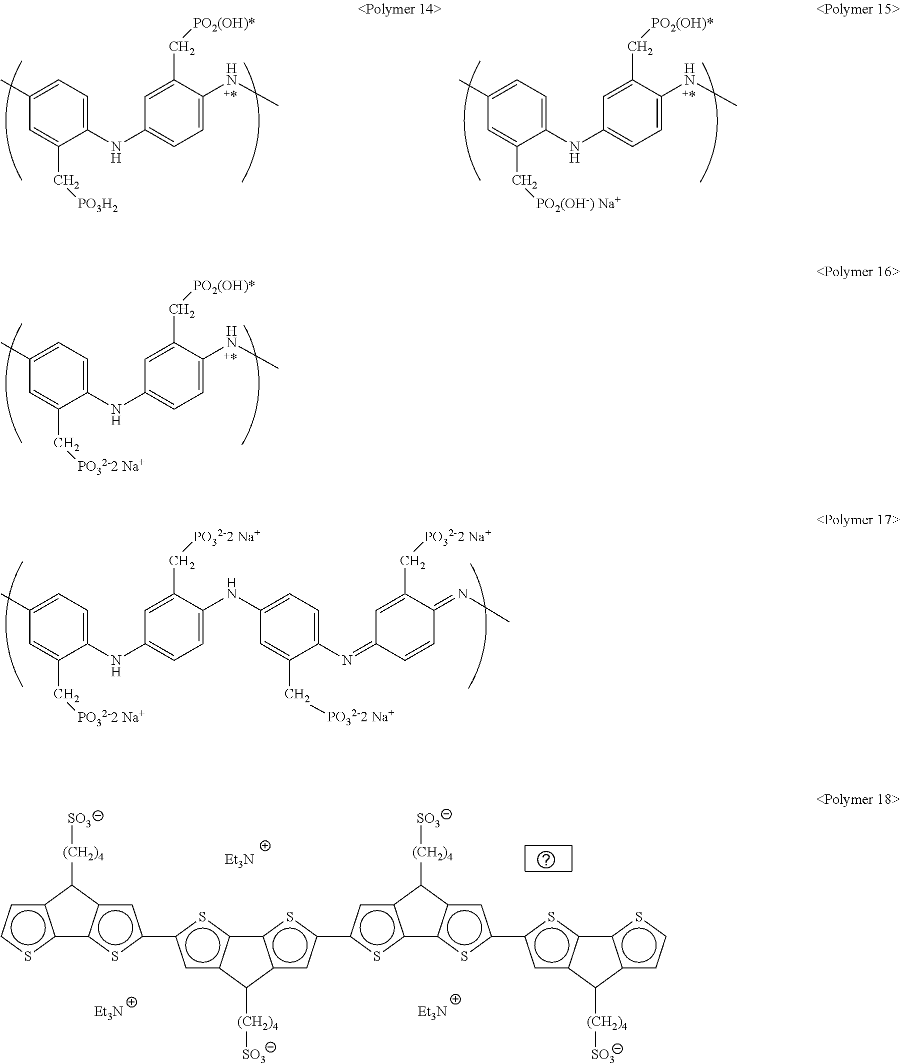

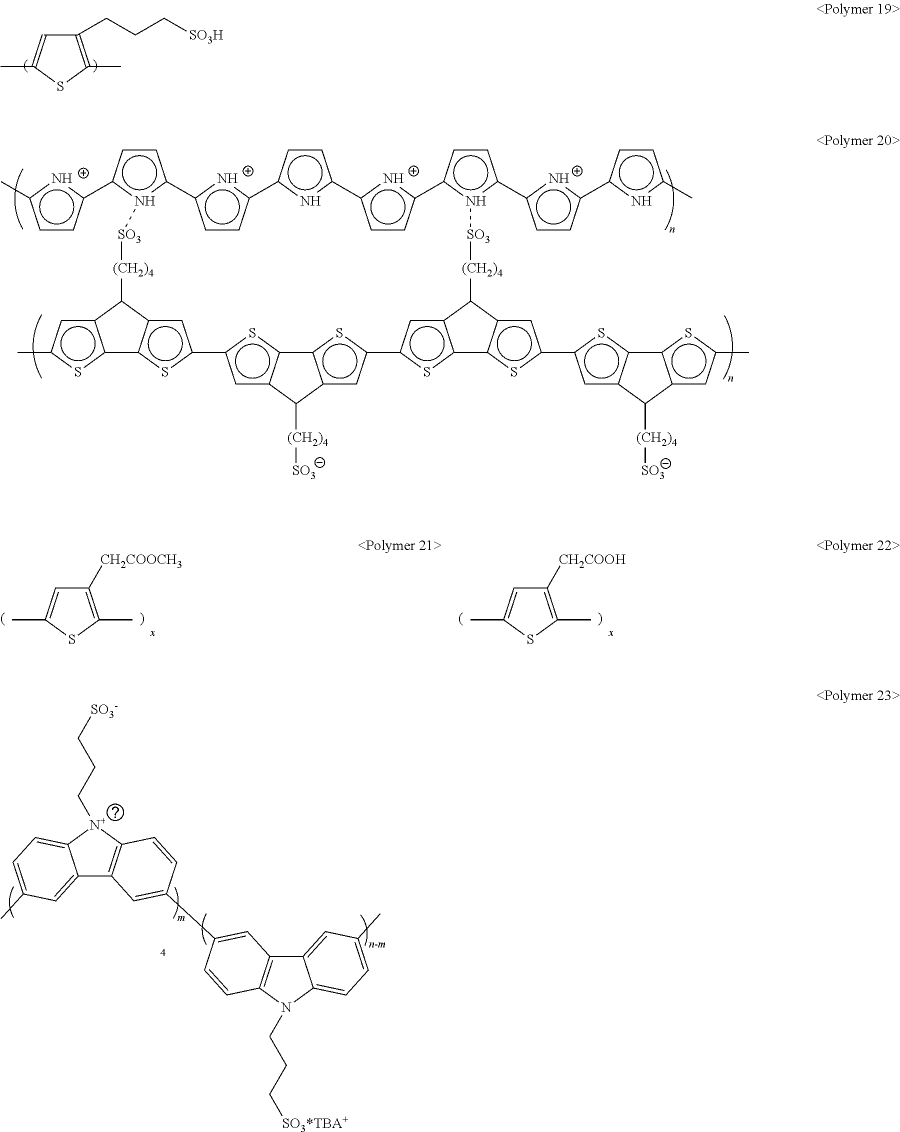

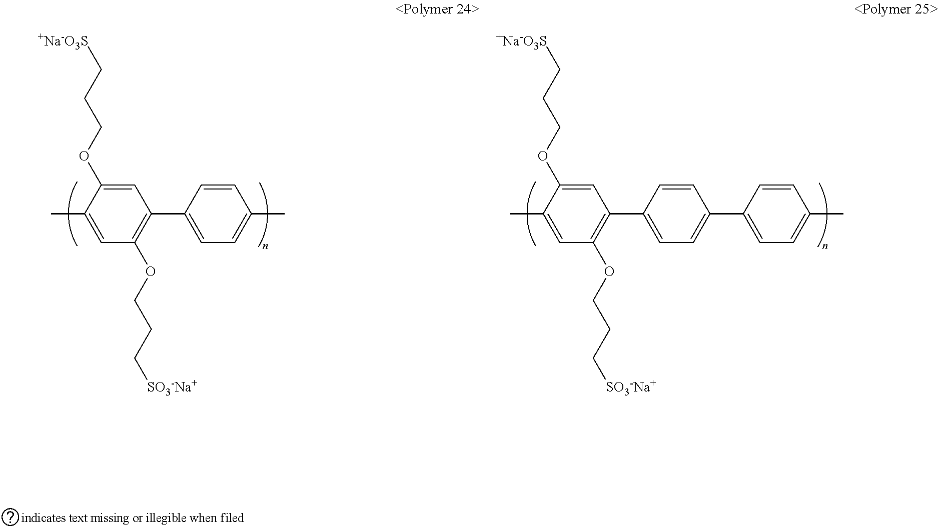

The first fluorine-based material included in the conductive layer 11, and the second fluorine-based material included in the surface energy-tuning layer 12 may each independently be an ionomer (a polymer containing an ionic group) represented by the following Formula 1:

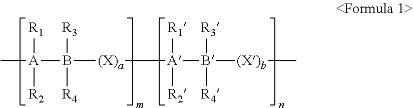

In Formula 1, 0<m≦10,000,000, 0≦n<10,000,000, 0≦a≦20, and 0≦b≦20;

A, B, A′, and B′ are each independently selected from the group consisting of C, Si, Ge, Sn, and Pb;

R₁, R₂, R₃, R₄, R₁′, R₂′, R₃′, and R₄′ are each independently selected from the group consisting of hydrogen, a halogen, a nitro group, a substituted or unsubstituted amino group, a cyano group, a substituted or unsubstituted C₁-C₃₀ alkyl group, a substituted or unsubstituted C₁-C₃₀ heteroalkyl group, a substituted or unsubstituted C₁-C₃₀ alkoxy group, a substituted or unsubstituted C₁-C₃₀ heteroalkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₂-C₃₀ heterocycloalkyl group, a substituted or unsubstituted C₁-C₃₀ alkylester group, a substituted or unsubstituted C₁-C₃₀ heteroalkylester group, a substituted or unsubstituted C₆-C₃₀ arylester group, and a substituted or unsubstituted C₂-C₃₀ heteroarylester group, provided that at least one of R₁, R₂, R₃, and R₄ is an ionic group, or includes the ionic group; and

X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₅-C₃₀ heterocycloalkylene group, a substituted or unsubstituted C₆-C₃₀ arylester group, and a substituted or unsubstituted C₂-C₃₀ heteroarylester group,

provided that, when n is 0, at least one of R₁, R₂, R₃, and R₄ may be a hydrophobic functional group containing a halogen element, or may include the hydrophobic functional group.

Such a hydrophobic functional group may, for example, include a halogenated C₁-C₃₀ alkyl, a halogenated C₁-C₃₀ alkoxy group, a halogenated C₁-C₃₀ heteroalkyl group, a halogenated C₁-C₃₀ heteroalkoxy group, a halogenated C₆-C₃₀ aryl group, a halogenated C₆-C₃₀ arylalkyl group, a halogenated C₆-C₃₀ aryloxy group, a halogenated C₂-C₃₀ heteroaryl group, a halogenated C₂-C₃₀ heteroarylalkyl group, a halogenated C₂-C₃₀ heteroaryloxy group, a halogenated C₅-C₂₀ cycloalkyl group, a halogenated C₂-C₃₀ heterocycloalkyl group, a halogenated C₁-C₃₀ alkylester group, a halogenated C₁-C₃₀ heteroalkylester group, a halogenated C₆-C₃₀ arylester group, and a halogenated C₂-C₃₀ heteroarylester group, all of which contain at least one of a halogen atom and a halogen element. For example, the hydrophobic functional group may be a halogen atom. Specifically, the hydrophobic functional group may be fluorine, but the present invention is not limited thereto.

When 0<n<10,000,000, the ionomer has a structure copolymerized with a non-ionic monomer containing no ionic groups. Thus, the content of the ionic group in the ionomer may be reduced within a proper range, resulting in a decreased content of residues decomposed by a reaction with electrons. In this case, the content of a non-ionic comonomer may be in a range of 1 mole % to 99 mole %, for example, 1 to 50 mole %, based on a total of the contents of the monomers required to form the ionomer. When the content of the comonomer satisfies this content range, an ionomer containing a sufficient content of the ionic group may be manufactured.

At least one of R₁, R₂, R₃, and R₄ in Formula 1 may be an ionic group, or may include the ionic group. In this case, the ionic group consists of a pair of an anionic group and a cationic group. Here, the anionic group may be selected from the group consisting of PO₃²⁻, SO₃⁻, COO⁻, I⁻, CHOSO₃⁻, CH₃COO⁻, and BO₂²⁻, and the cationic group may include at least one of a metal ion and an organic ion, the metal ion may be selected from the group consisting of Na⁺, K⁺, Li⁺, Mg⁺², Zn⁺², and Al⁺³, and the organic ion may be selected from the group consisting of H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, and RCHO⁺ (R is CH₃(CH₂)ₙ—; and n is an integer ranging from 0 to 50).

For example, the first fluorine-based material and the second fluorine-based material may each independently be an ionomer including at least one of repeating units represented by the following Formulas 2 to 13.

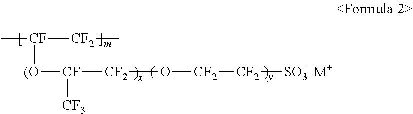

In Formula 2, m is an integer ranging from 1 to 10,000,000, x and y are each independently an integer ranging from 0 to 10, and M⁺ represents Na⁺, K⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

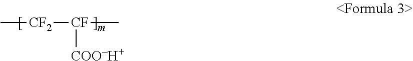

In Formula 3, m is an integer ranging from 1 to 10,000,000;

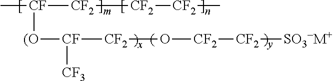

In Formula 4, m and n are 0<m≦10,000,000, and 0≦n<10,000,000, respectively, x and y are each independently an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

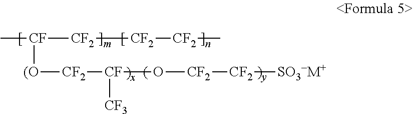

In Formula 5, m and n are 0<m≦10,000,000, and 0≦n<10,000,000, respectively, x and y are each independently an integer ranging from 0 to 20, and M⁺ represents Na⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

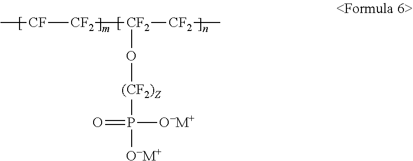

In Formula 6, m and n are 0<m≦10,000,000, and 0≦n<10,000,000, respectively, z is an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

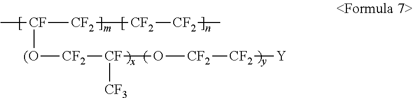

In Formula 7, m and n are 0<m≦10,000,000, and 0≦n<10,000,000, respectively, x and y are each independently an integer ranging from 0 to 20, Y is one selected from the group consisting of —COO⁻M⁺, —SO₃⁻NHSO₂CF₃⁺, and —PO₃²⁻(M⁺)₂, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

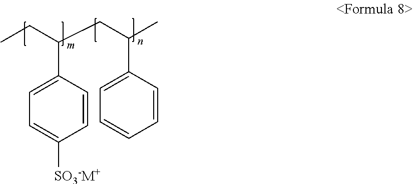

In Formula 8, m and n are 0<m≦10,000,000, and 0≦n<10,000,000, respectively, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

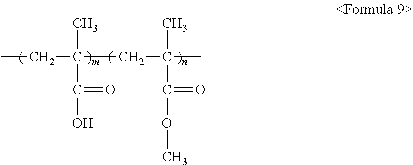

In Formula 9, m and n are 0<m≦10,000,000, and 0≦n<10,000,000, respectively;

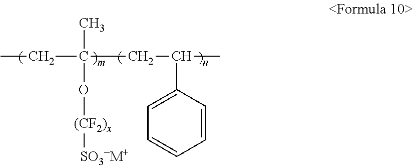

In Formula 10, m and n are 0<m≦10,000,000, and 0≦n<10,000,000, respectively, x is an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

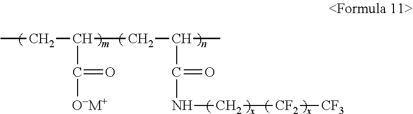

In Formula 11, m and n are 0<m≦10,000,000, and 0≦n<10,000,000, respectively, x and y are each independently an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

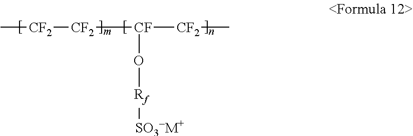

In Formula 12, m and n are 0<m≦10,000,000, and 0≦n<10,000,000, respectively, R_{f}=—(CF₂)_{z}— (z is an integer ranging from 1 to 50, provided that n is not 2), —(CF₂CF₂O)_{z}CF₂CF₂— (z is an integer ranging from 1 to 50), or —(CF₂CF₂CF₂O)_{z}CF₂CF₂— (z is an integer ranging from 1 to 50), and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50);

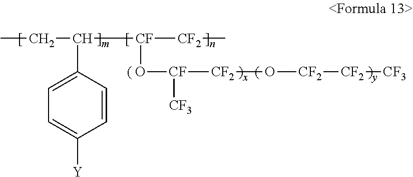

In Formula 13, m and n are 0<m≦10,000,000, and 0≦n<10,000,000, respectively, x and y are each independently an integer ranging from 0 to 20, Y is each independently one selected from the group consisting of —SO₃⁻M⁺, —COO⁻M⁺, —SO₃⁻NHSO₂CF₃⁺, or —PO₃²⁻(M⁺)₂, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50).

Also, the first fluorine-based material included in the conductive layer 11, and the second fluorine-based material included in the surface energy-tuning layer 12 may each independently be a fluorine-based polymer including a repeating unit represented by one of the following Formulas 14 to 19:

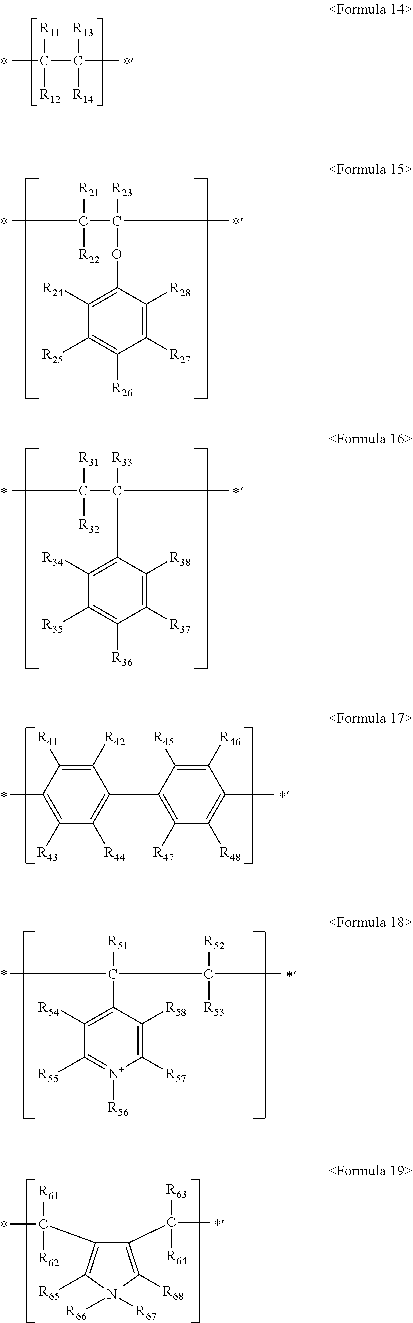

In Formulas 14 to 19, R₁₁ to R₁₄, R₂₁ to R₂₈, R₃₁ to R₃₈, R₄₁ to R₄₈, R₅₁ to R₅₈, and R₆₁ to R₆₈ are each independently selected from the group consisting of hydrogen, —F, a C₁-C₂₀ alkyl group (for example, a methyl group, an ethyl group, a propyl group, a butyl group, a pentyl group, a heptyl group, a hexyl group, and an octyl group), a C₁-C₂₀ alkoxy group (for example, a methoxy group, an ethoxy group, a propoxy group, a butoxy group, and a pentoxy group), a C₁-C₂₀ alkyl group substituted with at least one —F (for example, a methyl group, an ethyl group, a propyl group, a butyl group, a pentyl group, a heptyl group, a hexyl group, and an octyl group, all of which are substituted with at least one —F), a C₁-C₂₀ alkoxy group substituted with at least one —F (for example, a methoxy group, an ethoxy group, a propoxy group, a butoxy group, and a pentoxy group, all of which are substituted with at least one —F), Q₁, —O—(CF₂CF(CF₃)—O)ₙ—(CF₂)ₘ-Q₂ (where n and m are each independently an integer ranging from 0 to 20, provided that the sum of n and m is greater than or equal to 1), and —(OCF₂CF₂)ₓ-Q₃ (where x is an integer ranging from 1 to 20), provided that:

i) at least one of R₁₁ to R₁₄ in Formula 14,

ii) at least one of R₂₁ to R₂₈ in Formula 15,

iii) at least one of R₃₁ to R₃₈ in Formula 16,

iv) at least one of R₄₁ to R₄₈ in Formula 17,

v) at least one of R₅₁ to R₅₈ in Formula 18, and

v) at least one of R₆₁ to R₆₈ in Formula 19 are selected from the group consisting of —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂, and —(OCF₂CF₂)ₓ-Q₃.

That is, the fluorine-based polymer including the repeating unit represented by one of the above Formulas 14 to 19 absolutely includes —F, or a substituent containing —F (for example, a C₁-C₂₀ alkyl group substituted with at least one —F, etc.) present on at least one of the main chain and the side chain thereof.

Q₁ to Q₃ are each independently an ionic group.

The ionic group may include an anionic group and a cationic group.

In this case, the anionic group may be selected from the group consisting of PO₃²⁻, SO₃⁻, COO⁻, I⁻, CH₃COO⁻, and BO₂²⁻.

Meanwhile, the cationic group may include one or more types among a metal ion and an organic ion. Here, the metal ion may be selected from the group consisting of Na⁺, K⁺, Li⁺, Mg⁺², Zn⁺², and Al⁺³, and the organic ion may be selected from the group consisting of H⁺, CH₃(CH₂)ₙ₁NH₃⁺ (where n1 is an integer ranging from 0 to 50), NH₄⁺, NH₂⁺, NHSO₂CF₃⁺, CHO⁺, C₂H₅OH⁺, CH₃OH⁺, and RCHO⁺ (where R is CH₃(CH₂)ₙ₂—, and n2 is an integer ranging from 0 to 50).

For example, Q₁ to Q₃ may each independently be —SO₃H, —SO₃Na, —SO₃Li, —PO₃H₂, or —PO₃Na₂, but the present invention is not limited thereto.

The fluorine-based polymer may include at least one of the repeating units represented by Formulas 14 to 19. For example, there are various possible modified embodiments in which the fluorine-based polymer may be a homopolymer including the repeating unit represented by Formula 14, or a copolymer including the repeating unit represented by Formula 14 and the repeating unit represented by Formula 15.

For example, the fluorine-based polymer includes the repeating unit represented by Formula 14. In Formula 14, R₁₁ to R₁₃ may each independently be hydrogen, or —F, R₁₄ may be —O—(CF₂CF(CF₃)—O)ₙ—(CF₂)ₘ—SO₃H, or —O—(CF₂CF(CF₃)—O)ₙ—(CF₂)ₘ—PO₃H₂.

By way of another example, the fluorine-based polymer includes the repeating unit represented by Formula 15. In Formula 15, R₂₁ to R₂₃ may each independently be hydrogen, or —F, and at least one of R₂₄ to R₂₈ may be selected from the group consisting of —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂, and —(OCF₂CF₂)ₓ-Q₃.

By way of still another example, the fluorine-based polymer includes the repeating unit represented by Formula 15. In Formula 15, at least one of R₂₁ to R₂₃ may be —F, and at least one of R₂₄ to R₂₈ may be Q₁. For a definition of Q₁, see the definition as defined above.

By way of yet another example, the fluorine-based polymer includes the repeating unit represented by Formula 18. In Formula 18, R₅₁ to R₅₃ may each independently be hydrogen, or —F, and at least one of R₅₄ to R₅₈ may be selected from the group consisting of —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂, and —(OCF₂CF₂)ₓ-Q₃.

By way of yet another example, the fluorine-based polymer includes the repeating unit represented by Formula 19. In Formula 19, R₆₁ to R₆₄ may each independently be hydrogen, or —F, and at least one of R₆₅ to R₆₈ may be selected from the group consisting of —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂, and —(OCF₂CF₂)ₓ-Q₃.

According to one exemplary embodiment, the conductive thin film may include a fluorine-based polymer including a repeating unit represented by the following Formula 14A, but the present invention is not limited thereto:

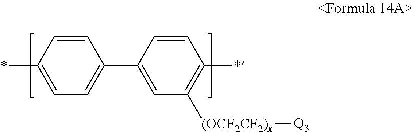

For descriptions of x and Q₃ in Formula 14A, see the descriptions as described above in this specification.

Meanwhile, the first fluorine-based material included in the conductive layer 11, and the second fluorine-based material included in the surface energy-tuning layer 12 may each independently be a fluorinated oligomer represented by the following Formula 20.

X-M^{f}ₙ-M^{h}ₘ-M^{a}ᵣ-G <Formula 20>

In Formula 20, X is an end group;

M^{f} represents a unit derived from a fluorinated monomer obtained from a condensation reaction of a perfluoropolyether alcohol, a polyisocyanate, and an isocyanate-reactive non-fluorinated monomer;

M^{h} represents a unit derived from a non-fluorinated monomer;

M^{a} represents a unit containing a silyl group represented by —Si(Y₄)(Y₅)(Y₆);

Y₄, Y₅, and Y₆ each independently represent a substituted or unsubstituted C₁-C₂₀ alkyl group, a substituted or unsubstituted C₆-C₃₀ aryl group, or a hydrolyzable substituent, provided that at least one of Y₄, Y₅, and Y₆ is the hydrolyzable substituent;

G is a monovalent organic group containing a residue of a chain transfer agent;

n is an integer ranging from 1 to 100;

m is an integer ranging from 0 to 100; and

r is an integer ranging from 0 to 100;

provided that the sum of n, m, and r is at least 2.

For example, in Formula 20, X may be a halogen atom, M^{f} may be a fluorinated C₁-C₁₀ alkylene group, M^{h} may be a C₂-C₁₀ alkylene group, Y₄, Y₅, and Y₆ may each independently be a halogen atom (Br, Cl, F, etc.), and p may be 0. For example, the fluorinated silane-based material represented by Formula 10 may be CF₃CH₂CH₂SiCl₃, but the present invention is not limited thereto.

In this specification, specific examples of the unsubstituted alkyl group may include a linear or branched alkyl group, for example, methyl, ethyl, propyl, isobutyl, sec-butyl, tert-butyl, pentyl, iso-amyl, hexyl, etc., and one or more hydrogen atoms included in the alkyl group may be substituted with a halogen atom, a hydroxyl group, a nitro group, a cyano group, a substituted or unsubstituted amino group (—NH₂, —NH(R), —N(R′)(R″) where R′ and R″ are each independently an alkyl group having 1 to 10 carbon atoms), an amidino group, a hydrazine or hydrazone group, a carboxyl group, a sulfonate group, a phosphate group, a C₁-C₂₀ alkyl group, a halogenated C₁-C₂₀ alkyl group, a C₁-C₂₀ alkenyl group, a C₁-C₂₀ alkynyl group, a C₁-C₂₀ heteroalkyl group, a C₆-C₂₀ aryl group, a C₆-C₂₀ arylalkyl group, a C₆-C₂₀ heteroaryl group, or a C₆-C₂₀ heteroarylalkyl group.

In this specification, the heteroalkyl group means that one or more carbon atoms, preferably, 1 to 5 carbon atoms in the main chain of the alkyl group are substituted with heteroatoms such as oxygen atoms, sulfur atoms, nitrogen atoms, phosphorus atoms, etc.

In this specification, the aryl group refers to a carbocyclic aromatic system containing one or more aromatic rings. In this case, the rings may be attached or fused together using a pendant method. Specific examples of the aryl group may include aromatic groups such as phenyl, naphthyl, tetrahydronaphthyl, etc. In this case, one or more hydrogen atoms in the aryl group may be substituted with the same substituents as in the alkyl group.

In this specification, the heteroaryl group refers to a cyclic aromatic system having 5 to 30 ring atoms, each of which contains 1, 2 or 3 heteroatoms selected from N, O, P, and S, and the remaining ring atoms are carbon (C). Here, the rings may be attached or fused together using a pendant method. In this case, one or more hydrogen atoms in the heteroaryl group may be substituted with the same substituents as in the alkyl group.

In this specification, the alkoxy group refers to a radical —O-alkyl. In this case, the alkyl is as defined above. Specific examples of the alkoxy group may include methoxy, ethoxy, propoxy, isobutyloxy, sec-butyloxy, pentyloxy, iso-amyloxy, hexyloxy, etc. In this case, one or more hydrogen atoms in the alkoxy group may be substituted with the same substituents as in the alkyl group.

As the substituent used in the present invention, the heteroalkoxy group has substantially the same meaning as the alkoxy, except that one or more heteroatoms, for example, oxygen, sulfur or nitrogen, may be present in an alkyl chain, and, for example, includes CH₃CH₂OCH₂CH₂O—, C₄H₉OCH₂CH₂OCH₂CH₂O—, CH₃O(CH₂CH₂O)ₙH, etc.

In this specification, the arylalkyl group means that some of hydrogen atoms in the aryl group as defined above are substituted with radicals such as lower alkyls, for example, methyl, ethyl, propyl, etc. For example, the arylalkyl group may include benzyl, phenylethyl, etc. In this case, one or more hydrogen atoms in the arylalkyl group may be substituted with the same substituents as in the alkyl group.

In this specification, the heteroarylalkyl group means that some of hydrogen atoms in the heteroaryl group are substituted with lower alkyl groups. Here, a definition of the heteroaryl in the heteroarylalkyl group is as described above. In this case, one or more hydrogen atoms in the heteroarylalkyl group may be substituted with the same substituents as in the alkyl group.

In this specification, the aryloxy group refers to a radical —O-aryl. In this case, the aryl is as defined above. Specific examples of the aryloxy group may include phenoxy, naphthoxy, anthracenyloxy, phenanthrenyloxy, fluorenyloxy, indenyloxy, etc. In this case, one or more hydrogen atoms in the aryloxy group may be substituted with the same substituents as in the alkyl group.

In this specification, the heteroaryloxy group refers to a radical —O-heteroaryl. In this case, the heteroaryl is as defined above.

In this specification, specific examples of the heteroaryloxy group may include a benzyloxy group, a phenylethyloxy group, etc. In this case, one or more hydrogen atoms in the heteroaryloxy group may be substituted with the same substituents as in the alkyl group.

In this specification, the cycloalkyl group refers to a monovalent monocyclic system having 5 to 30 carbon atoms. In this case, one or more hydrogen atoms in the cycloalkyl group may be substituted with the same substituents as in the alkyl group.

In this specification, the heterocycloalkyl group refers to a monovalent monocyclic system having 5 to 30 ring atoms, each of which contains 1, 2 or 3 heteroatoms selected from N, O, P, and S, and the remaining ring atoms are carbon (C). In this case, one or more hydrogen atoms in the cycloalkyl group may be substituted with the same substituents as in the alkyl group.

In this specification, the alkylester group refers to a functional group in which an ester group is bound to an alkyl group. In this case, the alkyl group is as defined above.

In this specification, the heteroalkylester group refers to a functional group in which an ester group is bound to a heteroalkyl group. In this case, the heteroalkyl group is as defined above.

In this specification, the arylester group refers to a functional group in which an ester group is bound to an aryl group. In this case, the aryl group is as defined above.

In this specification, the heteroarylester group refers to a functional group in which an ester group is bound to a heteroaryl group. In this case, the heteroaryl group is as defined above.

The amino group used in the present invention refers to —NH₂, —NH(R), or —N(R′)(R″), where R′ and R″ are each independently an alkyl group having 1 to 10 carbon atoms.

In this specification, the halogen is fluorine, chlorine, bromine, iodine, or astatine. Among these, fluorine is particularly preferred.

The surface energy-tuning layer 12 may have a thickness of 1 nm to 10 nm, for example, 1 nm to 5 nm. When the thickness of the surface energy-tuning layer 12 satisfies this thickness range, the work function of the conductive thin film may be easily adjusted.

The first fluorine-based material included in the conductive layer 11, and the second fluorine-based material included in the surface energy-tuning layer 12 may be the same or different from each other.

The conductive layer 11 may further include at least one additive selected from the group consisting of carbon nanotubes, graphene, reduced graphene oxide, metal nanowires, metal carbon nanodots, semiconductor quantum dots, semiconductor nanowires, and metal nanodots.

Also, the first electrode 10 may further include an auxiliary conductive thin film layer (not shown) disposed on a bottom surface of the conductive layer 11, and the auxiliary conductive thin film layer may include at least one selected from the group consisting of a conductive polymer, metallic carbon nanotubes, graphene, reduced graphene oxide, metal nanowires, a metal grid, carbon nanodots, semiconductor nanowires, and metal nanodots.

Such an auxiliary conductive thin film layer has an effect of improving the conductivity of the conductive layer 11.

A method of manufacturing such a first electrode 10 may include providing a first mixture, which includes the conductive polymer, the first fluorine-based material, and a first solvent, onto a substrate (not shown) and then removing at least a portion of the first solvent to form a conductive layer 11; and providing a second mixture, which includes the second fluorine-based material and a second solvent, onto the conductive layer 11 and then removing at least a portion of the second solvent to form a surface energy-tuning layer 12.

The substrate is a support on which a conductive thin film serving as the first electrode 10 will be formed. For example, the substrate may include glass, sapphire, silicon, silicon oxide, a metal foil (for example, copper foil, or aluminum foil), a steel substrate (for example, stainless steel, etc.), a metal oxide, a polymer substrate, and a combination of two or more types thereof. Examples of the metal oxide may include aluminum oxide, molybdenum oxide, indium oxide, tin oxide, and indium tin oxide, and examples of the polymer substrate may include Kapton foil, polyethersulfone (PES), polyacrylate (PAR), polyetherimide (PEI), polyethylene naphthalate (PEN), polyethylene terephthalate (PET), polyphenylene sulfide (PPS), a polyallylate, a polyimide, a polycarbonate (PC), triacetyl cellulose (TAC), cellulose acetate propinonate (CAP), etc., but the present invention is not limited thereto. Also, the substrate may be optionally a TFT substrate, or an insulating layer, and may be readily chosen according to the structure of an electronic element to be manufactured using the conductive thin film 10.

The first solvent is miscible with the conductive polymer and the first fluorine-based material, and may be a solvent which may be easily removed by a process such as heat treatment, etc. For example, the first solvent may include at least one selected from the group consisting of water, an alcohol, dimethyl formamide (DMF), dimethyl sulfoxide (DMSO), acetone, acetonitrile, toluene, dichlorobenzene, tetrahydrofuran, dichloroethane, trichloroethane, chloroform, and dichloromethane, but the present invention is not limited thereto.

The first mixture may be provided onto the substrate using known methods such as bar coating, shear coating, a casting method, a Langmuir-Blodgett (LB) method, spin coating, ink-jet printing, nozzle printing, a slot-die coating method, a spray coating method, screen printing, a doctor blade coating method, gravure printing, and offset printing.

Next, the first mixture provided onto the substrate may be heat-treated to remove at least a portion of the first solvent so as to form a conductive layer 11. The conditions for the heat treatment process may vary according to the types and contents of the conductive polymer and the first fluorine-based material used, but may be, for example, chosen from a range of 1 minute to 24 hours at 25° C. to 300° C.

Subsequently, the second mixture including the second fluorine-based material and the second solvent may be provided onto the conductive layer 11 using known methods such as bar coating, shear coating, a casting method, a Langmuir-Blodgett (LB) method, spin coating, ink-jet printing, nozzle printing, a spray coating method, a slot-die coating method, screen printing, a doctor blade coating method, gravure printing, and offset printing.

The second solvent may be selected from solvents which are miscible with the second fluorine-based material but are not substantially reactive with the conductive polymer. In this case, the second solvent may be easily chosen according to the selected conductive polymer and second fluorine-based material. For example, the second solvent may include at least one selected from the group consisting of water, an alcohol, dimethyl formamide (DMF), dimethyl sulfoxide (DMSO), acetone, acetonitrile, toluene, dichlorobenzene, tetrahydrofuran, dichloroethane, trichloroethane, chloroform, dichloromethane, and hydrofluoroether (HFE), but the present invention is not limited thereto.

Then, the second mixture provided onto the conductive layer 11 may be heat-treated to remove at least a portion of the second solvent so as to form the surface energy-tuning layer 12. The conditions for the heat treatment process may vary according to the type and content of the second fluorine-based material used, but may be chosen within a range of the heat treatment conditions used to form the conductive layer 11.

FIG. 2 is a schematic cross-sectional view of a first electrode according to another exemplary embodiment of the present invention.

Referring to FIG. 2, the first electrode 10′ according to another exemplary embodiment of the present invention may include a conductive layer 11, an interlayer 13 disposed on the conductive layer 11, and a surface energy-tuning layer 12 disposed on the interlayer 13.

For descriptions of the conductive layer 11 and the surface energy-tuning layer 12, see the descriptions of the conductive layer 11 and the surface energy-tuning layer 12 shown in FIG. 1, respectively.

The interlayer 13 is characterized by including a first fluorine-based material included in the conductive layer 11, and a second fluorine-based material included in the surface energy-tuning layer 12. In this case, the first fluorine-based material and the second fluorine-based material may be different from each other.

For example, the interlayer 13 may include a conductive polymer and a first fluorine-based material included in the conductive layer 11, and a second fluorine-based material included in the surface energy-tuning layer 12. In this case, the first fluorine-based material and the second fluorine-based material are different from each other.

The conductive polymer, the first fluorine-based material, and the second fluorine-based material included in the interlayer 13 may be uniformly or non-uniformly mixed with each other. For example, there are various possible modified embodiments in which the first fluorine-based material and the second fluorine-based material included in the interlayer 13 may have a concentration gradient formed to decrease in a direction spanning from the surface energy-tuning layer 12 to the conductive layer 11.

Therefore, when the first and second fluorine-based materials have such a decreasing concentration gradient, a work function-tuning layer and an auxiliary conductive layer may be effectively separated in the conductive layer 11 to promote the injection of holes into the semiconductor layers, thereby improving device performance.

The method of manufacturing a first electrode 10′ may include providing a first mixture, which includes the conductive polymer, the first fluorine-based material, and a first solvent, onto a substrate (not shown) and then removing at least a portion of the first solvent to form a conductive layer 11; and providing a second mixture, which includes the second fluorine-based material and a second solvent, onto the conductive layer 11 and then removing at least a portion of the second solvent to form a surface energy-tuning layer 12 and an interlayer 13 at the same time.

As a specific example, a first layer including the conductive polymer, the first fluorine-based material, the second fluorine-based material, and the second solvent may be formed, and a second layer including the second fluorine-based material and the second solvent may be formed on the first layer when the second mixture is provided onto the conductive layer 11, and the interlayer 13 including the conductive polymer, the first fluorine-based material, and the second fluorine-based material, and the surface energy-tuning layer 12 including the second fluorine-based material but not comprising the conductive polymer may be formed at the same time by removing the second solvent.

For the formation of the conductive layer 11, see the formation of the conductive layer 11 as shown in FIG. 1.

When a solvent miscible with the conductive polymer and the first fluorine-based material is selected as the second solvent of the second mixture to be provided onto the conductive layer 11, a surface of the conductive layer 11 may react with (for example, may be partially dissolved in) the second solvent as the second mixture is provided onto the conductive layer 11. As a result, the first layer including the conductive polymer, the first fluorine-based material, the second fluorine-based material, and the second solvent may be formed on the conductive layer 11, and the second layer including the second fluorine-based material and the second solvent may be formed on the first layer.

Thereafter, the interlayer 13 including the conductive polymer, the first fluorine-based material, and the second fluorine-based material, and the surface energy-tuning layer 12 including the second fluorine-based material but not including the conductive polymer may be formed at the same time by performing a process for removing at least a portion of the second solvent of the first layer and second layer, for example, a heat treatment process (for the heat treatment conditions, see the above-described conditions for the heat treatment).

The conductivity of such first electrodes 10 and 10′ as shown in FIGS. 1 and 2 may depend on a material of the conductive layer, and thus the first electrode 10 or 10′ may have a conductivity of 1×10⁻⁷ S/cm to 1×10⁶ S/cm, based on a thickness of 100 nm. For example, when the first electrode 10 or 10′ is used as the anode, the first electrode 10 or 10′ may have a conductivity of at least 0.1 S/cm to 1×10⁶ S/cm, based on a thickness of 100 nm.

The surface energy-tuning layer 12 which has substantially no conductive polymer is present on a surface of the first electrode 10 or 10′ as described above. Therefore, the surface energy and work function of the first electrode 10 or 10′ may be determined by the surface energy-tuning layer, regardless of the conductive layer formed therebelow, while maintaining the high conductivity of the first electrode 10 or 10′, and thus, the work function conditions required for metal halide perovskite light emitting devices may be effectively satisfied.

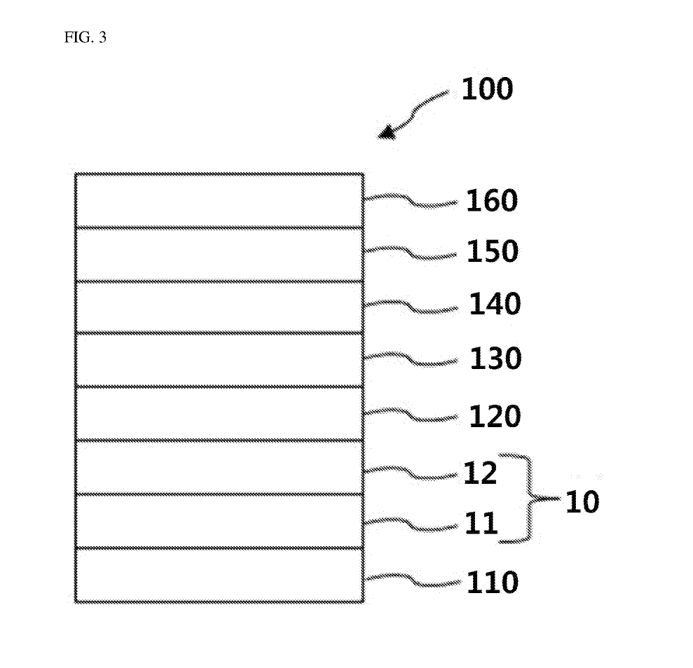

FIG. 3 is a schematic cross-sectional view of a metal halide perovskite light emitting device according to one exemplary embodiment of the present invention.

Referring to FIG. 3, the metal halide perovskite light emitting device according to one exemplary embodiment of the present invention includes a substrate 110, a first electrode 10, a hole transport layer 120, a metal halide perovskite light emitting layer 130, an electron transport layer 140, an electron injection layer 150, and a second electrode 160. The hole transport layer 120 or the electron transport layer 140 may show the same performance even when the hole transport layer 120 or the electron transport layer 140 is selectively removed.

The first electrode 10 may be a conductive thin film including the conductive layer 11 and the surface energy-tuning layer 12. As described above, the conductive layer 11 includes the conductive polymer and the first fluorine-based material, and the surface energy-tuning layer 12 includes the second fluorine-based material, but does not include a conductive polymer included in the conductive layer 11.

Here, the first fluorine-based material and the second fluorine-based material may be the same or different from each other.

In this case, when the first electrode 10 is an anode, the second electrode 160 may be a cathode.

When a voltage is applied between the anode 10 and the cathode 160 of the metal halide perovskite light emitting device 100, holes injected from the first electrode 10 move to the light emitting layer 130 via the hole transport layer 120, and electrons injected from the cathode 160 move to the light emitting layer 130 via the electron injection layer 150 and the electron transport layer 140. Carriers such as the holes and the electrons are recombined in the light emitting layer 130 to generate excitons. In this case, light is generated as the excitons transit from an excited state to a ground state. When the metal halide perovskite light emitting device 100 does not include the hole transport layer 120, the first electrode 10 in the metal halide perovskite light emitting device 100 may serve as an anode, a hole injection layer, a hole transport layer, or a functional layer having both of hole injection and transport functions.

A substrate used in a conventional semiconductor process may be used as the substrate 110. For example, the substrate 110 may include silicon, silicon oxide, a metal foil (for example, copper foil, aluminum foil, stainless steel, etc.), a metal oxide, a polymer substrate, and a combination of two or more types thereof. The metal foil may be made of a material which has a high melting point and does not serve as a catalyst capable of forming graphene. Examples of the metal oxide may include aluminum oxide, molybdenum oxide, indium tin oxide, etc., and examples of the polymer substrate may include Kapton foil, polyethersulfone (PES), polyacrylate (PAR), polyetherimide (PEI), polyethylene naphthalate (PEN), polyethylene terephthalate (PET), polyphenylene sulfide (PPS), a polyallylate, a polyimide, a polycarbonate (PC), triacetyl cellulose (TAC), cellulose acetate propinonate (CAP), etc., but the present invention is not limited thereto.

For example, the substrate 110 may be the polymer substrate as described above, but the present invention is not limited thereto.

The first electrode 10 is disposed on the substrate 110. Such a first electrode 10 may be an electrode as shown in FIG. 1. Therefore, the first electrode 10 may include a conductive layer 11 and a surface energy-tuning layer 12 disposed on the conductive layer 11. Meanwhile, by way of another example, the first electrode 10 may be an electrode as shown in FIG. 2.

Therefore, the surface energy-tuning layer 12, which includes the second fluorine-based material and does not include the conductive polymer, is arranged below the light emitting layer 130. Here, since the absolute value of an ionization potential level of the surface energy-tuning layer 12 is higher than the absolute value of an ionization potential (or highest occupied molecular orbital (HOMO) energy) level of the light emitting layer 130, the transport of holes from the surface energy-tuning layer 12 to the light emitting layer 130 may be smoothly achieved. As a result, since the exciton generation efficiency at the light emitting layer 130 may be enhanced, the metal halide perovskite light emitting device 100 may have characteristics such as high efficiency, low driving voltage, long lifespan, etc.

The method of manufacturing the first electrode 10 are described above as shown in FIGS. 1 and 2, and thus a description thereof is omitted.

Meanwhile, the conductive layer 11 of the first electrode 10 may further include at least one additive selected from the group consisting of carbon nanotubes, graphene, reduced graphene oxide, metal nanowires, metal carbon nanodots, semiconductor quantum dots, semiconductor nanowires, and metal nanodots.

In this case, the first electrode 10 may be formed by providing at least one of a conductive polymer (the conductivity of the conductive polymer is greater than or equal to 100 S/cm), metallic carbon nanotubes, graphene, reduced graphene oxide, metal nanowires, a metal grid, carbon nanodots, semiconductor nanowires, and metal nanodots onto the substrate 110 using methods such as a spin coating method, bar coating, shear coating, a casting method, a Langmuir-Blodgett (LB) method, an ink-jet printing method, a nozzle printing method, slot-die coating, a doctor blade coating method, a screen printing method, a dip coating method, a gravure printing method, a reverse-offset printing method, a physical transfer method, a spray coating method, a chemical vapor deposition method, a thermal evaporation method, etc.

In this case, the conductive layer 11 may be formed by applying a mixture, which includes i) at least one of a conductive polymer, metallic carbon nanotubes, graphene, reduced graphene oxide, metal nanowires, carbon nanodots, semiconductor nanowires, and metal nanodots, and ii) a third solvent, onto a substrate, and then heat-treating the mixture to remove the third solvent. For examples of the third solvent, see the examples of the above-described first and second solvents.

According to one exemplary embodiment, an auxiliary conductive thin film layer (not shown) configured to improve conductivity of the anode or improve optical characteristics and give a surface plasmon effect may be provided between the substrate 110 and the first electrode 10 serving as the anode.

For example, the auxiliary conductive thin film layer may include at least one selected from the group consisting of a conductive polymer, metallic carbon nanotubes, graphene, reduced graphene oxide, metal nanowires, a metal grid, carbon nanodots, semiconductor nanowires, and metal nanodots.

According to one exemplary embodiment, when the auxiliary conductive thin film layer includes graphene, the auxiliary conductive thin film layer may be formed by physically transferring a graphene sheet onto the substrate 110.

According to another exemplary embodiment, when the conductive layer 11 includes the metallic carbon nanotubes, the auxiliary conductive thin film layer may be formed by growing the metallic carbon nanotubes on the substrate 110 or providing the carbon nanotubes dispersed in a solvent onto the substrate 110 using a solution-based printing method (i.e., a spray coating, spin coating, dip coating, gravure coating, reverse-offset coating, screen printing, or slot-die coating method) and removing the solvent.

According to still another exemplary embodiment, when the conductive layer 11 includes the metal grid, the auxiliary conductive thin film layer may be formed by vacuum-depositing a metal onto the substrate 110 to form a metal film, and then patterning the metal film in various mesh shapes using photolithography, or dispersing a metal precursor or metal particles in a solvent and subjecting the resulting dispersion to a printing method (i.e., a spray coating, spin coating, dip coating, gravure coating, reverse-offset coating, screen printing, or slot-die coating method).

The hole transport layer 120 is disposed on the first electrode 10. The hole transport layer 120 material may be a material in which hole mobility is higher than electron mobility in the same electric field. For example, the hole transporting material may be a material for the hole injection layer or the hole transport layer of the organic light emitting device. For example, examples of the hole transporting material may include 1,3-bis(carbazol-9-yl)benzene (MCP), 1,3,5-tris(carbazol-9-yl)benzene (TCP), 4,4′, 4″-tris(carbazol-9-yl)triphenylamine (TcTa), 4,4′-bis(carbazol-9-yl)biphenyl (CBP), N,N′-bis(naphthalen-1-yl)-N,N′-bis(phenyl)benzidine (NPB), N,N′-bis(naphthalen-2-yl)-N,N′-bis(phenyl)-benzidine (β-NPB), N,N′-bis(naphthalen-1-yl)-N,N′-bis(phenyl)-2,2′-dimethylbenzidine (α-NPD), di-[4,-(N,N-ditolyl-amino)-phenyl]cyclohexane (TAPC), N,N,N′,N′-tetra-naphthalen-2-yl-benzidine (β-TNB), and N4,N4,N4′,N4′-tetra(biphenyl-4-yl)biphenyl-4,4′-diamine (TPD15), but the present invention is not limited thereto.

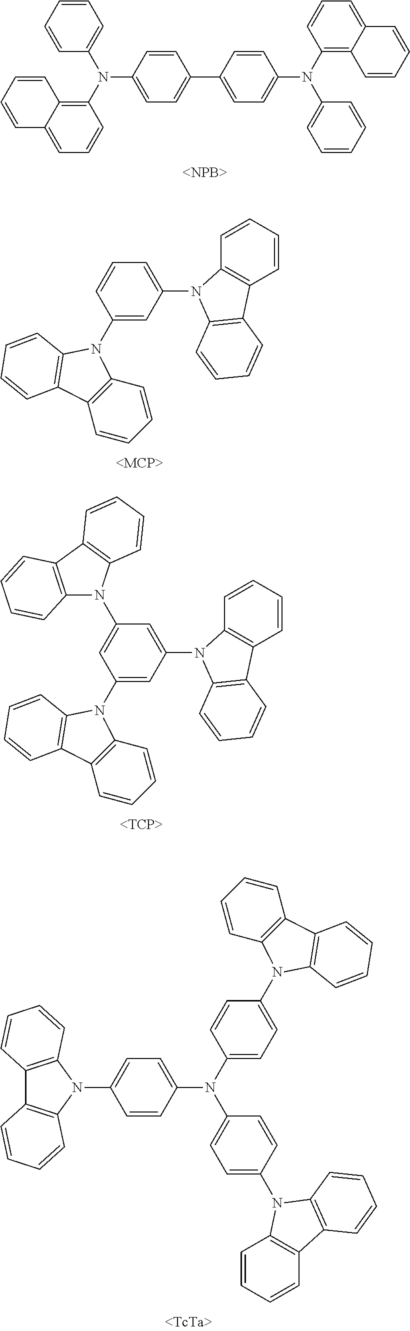 [SMILES: c1ccc(N(c2ccc(-c3ccc(N(c4ccccc4)c4cccc5ccccc45)cc3)cc2)c2cccc3ccccc23)cc1 ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

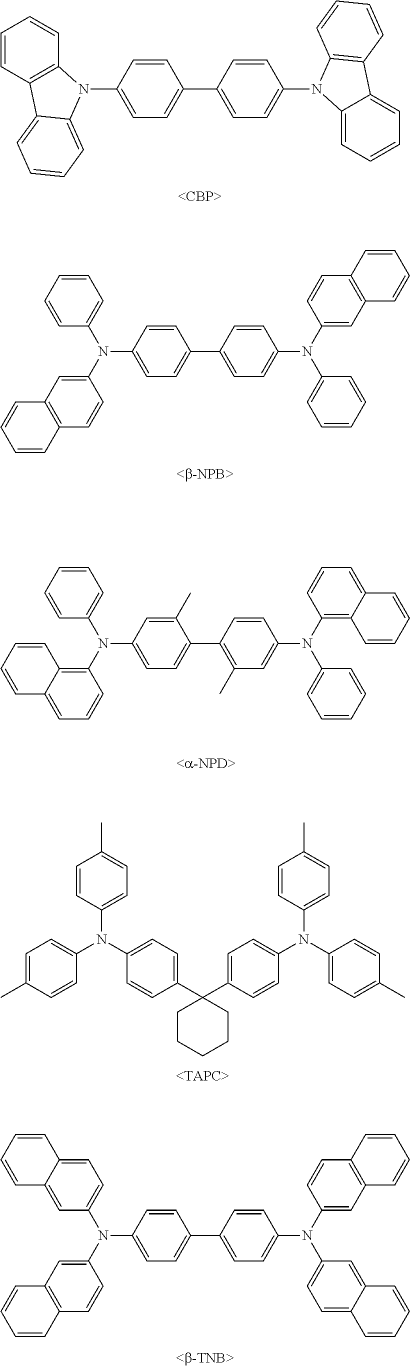

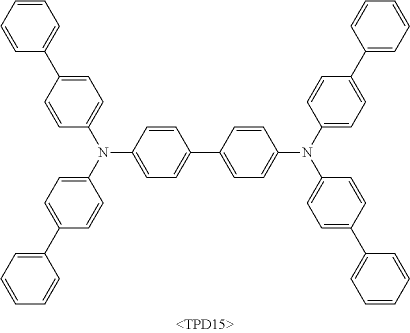 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

The light emitting layer 130 is disposed on the hole transport layer 120. Such a light emitting layer 130 may include a metal halide perovskite material.

The metal halide perovskite material may have compositions of ABX₃, A₂BX₄, ABX₄ or Aₙ₋₁PbₙI₃ₙ₊₁ (n is an integer ranging from 2 to 6), where A may be a monovalent organic cation or a monovalent metal cation, B may be a divalent metal ion, and X may be a monovalent halide ion.

For example, the metal halide perovskite material is characterized in that A may be an amidinium-based organic ion, an organic ammonium cation, or a monovalent alkali metal cations, B may be Pb, Mn, Cu, Ga, Ge, In, Al, Sb, Bi, Po, Sn, Eu, Yb, Ni, Co, Fe, Cr, Pd, Cd, Ca, Sr, or a combination thereof, and X may be Cl, Br, I, or a combination thereof.

More specifically, metal halide perovskites have a crystal structure in which a core metal (M) is positioned in the center and six halogen elements (X) are positioned at all faces of a hexahedron as a face-centered cubic (FCC) structure, or eight organic ammonium (RNH₃) cations are positioned at all vertexes of the hexahedron as body-centered cubic (BCC) structure.

In this case, the hexahedron has all faces formed at an angle of 90°, and has a tetragonal structure in which sides have different lengths in width, height and depth directions as well as a cubic structure in which sides have the same lengths in width, height and depth directions.

Therefore, a two-dimensional structure according to one exemplary embodiment of the present invention is a nanocrystal structure of a metal halide perovskite in which a core metal (M) is positioned in the center and six halogen elements (X) are positioned at all faces of a hexahedron as a face-centered cubic (FCC) structure, or eight organic ammonium (RNH₃) cations are positioned at all vertexes of the hexahedron as body-centered cubic (BCC) structure, and thus is defined as a structure in which the sides have the same lengths in width and height directions and a length in a depth direction at least 1.5 times the lengths in width and height directions.

The metal halide perovskite material of the metal halide perovskite light emitting layer 130 may have a perovskite crystal structure as organic and inorganic substances are mixed. In the metal halide perovskite material of the metal halide perovskite light emitting layer 130, each of the organic and inorganic substances may be formed of CH₃NH₃, Pb, and X, but the present invention is not limited thereto. X may be Cl, Br, or I. X (a halogen element) used in the metal halide perovskite material of the metal halide perovskite light emitting layer 130 may be one or two or more elements. For example, the metal halide perovskite material may be CH₃NH₃PbX₃. X may be Cl, Br, I, or a combination thereof.

For example, the metal halide perovskite material may be CH₃NH₃PbBr₃, CH₃NH₃PbBr₃₋ₓIₓ, or CH₃NH₃PbBr₃₋ₓClₓ. The metal halide perovskite may have a structure of A₂BX₄, ABX₄ or Aₙ₋₁PbₙI₃ₙ₊₁ (n is an integer ranging from 2 to 6), all of which have a lamellar-type 2D structure. Here, A is an organic ammonium material, B is a metal material, and X is a halogen element. For example, A may be (CH₃NH₃)ₙ, ((CxH₂ₓ₊₁)ₙNH₃)₂(CH₃NH₃)ₙ, (RNH₃)₂, (CₙH₂ₙ₊₁NH₃)₂, (CF₃NH₃), (CF₃NH₃)ₙ, ((CₓF₂ₓ₊₁)ₙNH₃)₂(CF₃NH₃)ₙ, ((CₓF₂ₓ₊₁)ₙNH₃)₂, or (CₙF₂ₙ₊₁NH₃)₂ (n is an integer greater than or equal to 1), and B may be a divalent transition metal, a rare earth metal, an alkaline earth metal, Pb, Sn, Ge, Ga, In, Al, Sb, Bi, Po, or a combination thereof. In this case, the rare earth metal may, for example, be Ge, Sn, Pb, Eu, or Yb. Also, the alkaline earth metal may, for example, be Ca or Sr. In addition, X may be Cl, Br, I, or a combination thereof.

Such a light emitting layer 130 may be formed through a method such as spin coating, bar coating, spray coating, or vacuum deposition.

For example, the method of manufacturing the metal halide perovskite light emitting layer 130 may include starting a coating process by dropping a metal halide perovskite light emitting layer solution for forming a metal halide perovskite light emitting layer onto a substrate on which a first electrode and a hole transport layer are formed, and forming a light emitting layer having a controlled crystal grain size by dropping an organic solution including a low-molecular-weight organic substance before a solvent is evaporated from the metal halide perovskite light emitting layer solution during the coating process.

For example, the metal halide perovskite solution may be prepared by mixing CH₃NH₃Br and PbBr₂ at a ratio of 1.05:1 to 1:1 and dissolving the resulting mixture in a polar organic solvent. For example, the polar organic solvent may be dimethyl sulfoxide or dimethyl formamide. For example, the metal halide perovskite solution, CH₃NH₃PbBr₃, may be prepared by mixing CH₃NH₃Br and PbBr₂ at a ratio of 1.05:1 and dissolving 40% by weight of the resulting mixture in dimethyl sulfoxide (DMSO).

The electron transport layer 140 is disposed on the light emitting layer 130. For example, the electron transport layer 140 may be formed on the light emitting layer 130 or a hole blocking layer according to a method optionally selected from various known methods such as a vacuum deposition method, a spin coating method, a casting method, an LB method, etc. In this case, the deposition and coating conditions vary according to the type of a target compound, a desired layer structure, and thermal characteristics, but may be chosen within a similar range of the conditions used to form the hole injection layer as described above.

A known electron transport material may be used as a material of the electron transport layer 140. For example, known materials such as tris(8-quinolinolate)aluminum (Alq₃), TAZ, 4,7-diphenyl-1,10-phenanthroline (Bphen), BCP, BeBq₂, BAlq, and the like may be used as the material of the electron transport layer 140.

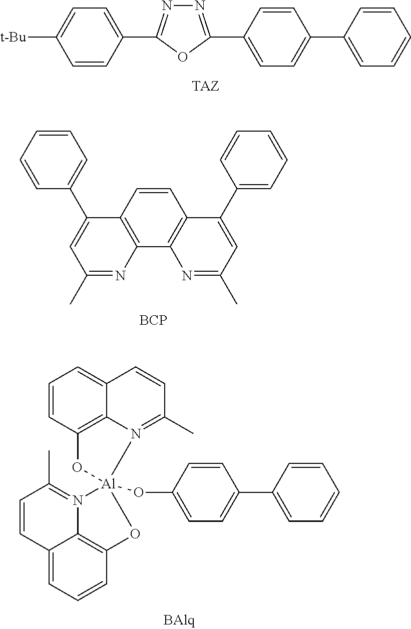

The electron transport layer 140 may have a thickness of approximately 10 nm to 100 nm, for example, 20 nm to 50 nm. When the thickness of the electron transport layer 140 satisfies this thickness range, excellent electron transport characteristics may be obtained without an increase in driving voltage.

The electron injection layer 150 may be formed on the electron transport layer 140. Known electron injection materials, for example, LiF, NaCl, NaF, CsF, Li₂O, BaO, BaF₂, Cs₂CO₃, lithium quinolate (Liq), and the like, may be used as a material used to form the electron injection layer. In this case, the conditions for deposition of the electron injection layer 150 vary according to the type of a compound used, but may be generally chosen within substantially the same range of the conditions used to form a hole injection layer 120.

The electron injection layer 150 is disposed on the electron transport layer 140.

The electron injection layer 150 may have a thickness of approximately 0.1 nm to 10 nm, for example, 0.5 nm to 5 nm. When the thickness of the electron injection layer 150 satisfies this thickness range, a satisfactory level of electron injection characteristics may be obtained without a substantial increase in driving voltage.

Also, the electron injection layer 150 may include the metal derivative, such as LiF, NaCl, CsF, NaF, Li₂O, BaO, or Cs₂CO₃, at a content of 1 mole % to 50 mole % in the material for the electron transport layer, such as Alq₃, TAZ, Balq, Bebq₂, BCP, TBPI, TmPyPB, or TpPyPB, and thus may also be formed as a layer having a thickness of 1 nm to 100 nm, in which the material of the electron transport layer is doped with a metal such as Li, Ca, Cs, and Mg.

The second electrode 160 is disposed on the electron injection layer 150. When the first electrode 10 is an anode, the second electrode 160 may be a cathode (an electron injection electrode).

In this case, a metal having a relatively low work function, an alloy, an electrically conductive compound, or a combination thereof may be used as the second electrode 160. Specific examples of the second electrode 160 may include lithium (Li), magnesium (Mg), aluminum (Al), aluminum-lithium (Al—Li), calcium (Ca), and magnesium-indium (Mg—In), magnesium-silver (Mg—Ag), etc. Also ITO, IZO, and the like may be used to obtain top emission devices.

### EXAMPLES

### Preparative Example 1: Manufacture of Conductive Layer

For a conductive layer, a mixture including a highly conductive poly(3,4-ethylenedioxythiophene):poly(styrenesulfonate) (PEDOT:PSS) solution (PH500 commercially available from H.C. Starck GmbH: having a PSS content of 2.5 parts by weight per 1 part by weight of PEDOT and a conductivity of 0.3 S/cm), a solution of the following polymer 100 (5% by weight of polymer 100 was dispersed in a mixture of water and an alcohol (water:alcohol=4.5:5.5 (v/v)); commercially available from Aldrich Co. Ltd.), and 5% by weight of dimethyl sulfoxide (DMSO) was prepared. Here, a mixing ratio of the PEDOT:PSS solution and the solution of polymer 100 was adjusted so that the content (based on solid contents) of polymer 100 per 1 part by weight of PEDOT was 1.0 parts by weight

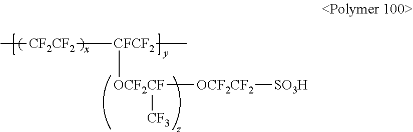

(In polymer 100, x=1,300, y=200, and z=1)

The mixture was spin-coated onto a glass substrate, and then heat-treated at 200° C. for 10 minutes to form a conductive layer 1 having a thickness of 100 nm. The conductivity of the conductive layer 1 was 125 S/cm (measured using a 4-point probe).

Next, each of conductive layers 2, 3 and 4 was formed on a glass substrate in the same manner as in the method of manufacturing the conductive layer 1, except that the mixing ratio of the PEDOT:PSS solution and the solution of polymer 100 was adjusted so that the contents of polymer 100 per 1 part by weight of PEDOT were 2.3 parts by weight, 4.9 parts by weight, and 11.2 parts by weight, and the conductive layers were then formed.

The conductivities of the conductive layers 2, 3 and 4 were 75 S/cm, 61 S/cm, and 50 S/cm (measured using a 4-point probe), respectively, as listed in Table 1. Then, the conductivities were measured using DSA100 commercially available from KRÜSS GmbH, and the surface energy was then measured using an Owens-Wendt method.

### Comparative Example A

An electrode A was manufactured in the same manner as in the method of manufacturing the conductive layer 1, except that a mixture including the PEDOT:PSS (PH500 commercially available from H.C. Starck GmbH) solution and 5% by weight of DMSO and not including the solution of polymer 100 used in Preparative Example 1 was used to form a thin film.

### Evaluation Example 1: Evaluation of Conductive Layers

<Evaluation of Work Function and Conductivity>

The work functions of the conductive layers 1 to 4, and the electrode A were evaluated using ultraviolet photoelectron spectroscopy in air (commercially available from Niken Keiki; Model Name: AC2). The evaluation results are as listed in the following Table 1.

TABLE 1

| | PEDOT/PSS/ | Work | | Surface |
|---|---|---|---|---|
| | polymer 100 | function | Conductivity | energy |
| | (weight ratio) | (eV) | (S/cm) | (mN/m) |
| Electrode | 1/2.5/0 | 4.73 | 300 | ~38 |
| A | | | | |
| Conductive | 1/2.5/1.0 | 5.07 | 125 | ~21 |
| layer 1 | | | | |
| Conductive | 1/2.5/2.3 | 5.23 | 75 | ~21 |
| layer 2 | | | | |
| Conductive | 1/2.5/4.9 | 5.64 | 61 | ~22 |
| layer 3 | | | | |
| Conductive | 1/2.5/11.2 | 5.80 | 50 | ~23 |
| layer 4 | | | | |

### Preparative Example 2: Manufacture of First Electrode (Anode)

A solution obtained by diluting the solution of polymer 100 with isopropyl alcohol (1:10, v/v) was spin-coated onto the conductive layer 4 described in Preparative Example 1 at 4,500 rpm for 90 seconds, and then heat-treated at 150° C. for 201 nanoseconds to form a surface energy-tuning layer on the conductive layer 4, thereby manufacturing a first electrode.

### Preparative Example 3: Manufacture of Metal Halide Perovskite Light Emitting Device

As an anode, a first electrode was formed on a glass substrate according to the method described in Preparative Example 2, and then CH₃NH₃Br and PbBr₂ were mixed at a ratio of 1.05:1, and 40% by weight of the resulting mixture was dissolved in dimethyl sulfoxide (DMSO). Thereafter, a CH₃NH₃PbBr₃ solution was spin-coated to form a CH₃NH₃PbBr₃ light emitting layer having a thickness of 300 nm.

A 50 nm-thick TPBi electron transport layer, a 1 nm-thick LiF electron injection layer, and a 100 nm-thick Al cathode (a second electrode) were sequentially formed on the CH₃NH₃PbBr₃ light emitting layer (this was performed using a vacuum deposition method) to manufacture a metal halide perovskite light emitting device 1

### Comparative Example 2

A light emitting device A was manufactured in the same manner as in Preparative Example 3, except that the conductive layer of Comparative Example 1 was used as the anode instead of the first electrode prepared in Preparative Example 3.

### Evaluation Example 2: Evaluation of Metal Halide Perovskite Light Emitting Devices

The efficiency, brightness, and lifespans of the light emitting devices 1 and A were evaluated using a Keithley 236 Source measuring unit and a Minolta CS 2000 spectroradiometer. The evaluation results are listed in the following Table 2.

TABLE 2

| | Current luminous efficiency (cd/A) |
|---|---|
| Light emitting device 1 | 21.41 |
| Light emitting device A | 1.14 |

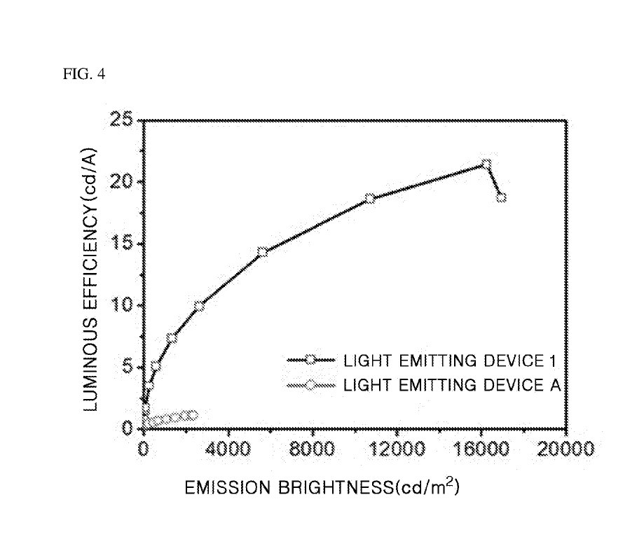

FIG. 4 is a graph illustrating luminous efficiency characteristics of the metal halide perovskite light emitting device according to one exemplary embodiment of the present invention.

Referring to FIG. 4, it can be seen that the light emitting device 1 has superior efficiency compared to the light emitting device A.

According to the exemplary embodiments of the present invention, the first electrode has excellent conductivity, can easily adjust a work function, and can prevent the dissociation of excitons between a metal halide perovskite light emitting layer and a first electrode, thereby maximizing brightness and efficiency of a metal halide perovskite light emitting device.

While the example embodiments of the present invention and their advantages have been described in detail, it should be understood that various changes, substitutions and alterations may be made herein without departing from the scope of the invention.

What is claimed is:

1. A metal halide perovskite light emitting device comprising:
a substrate;
a first electrode disposed on the substrate;
a light emitting layer disposed on the first electrode and comprising a metal halide perovskite material; and
a second electrode disposed on the light emitting layer,
wherein the first electrode comprises a conductive layer and a surface energy-tuning layer disposed on the conductive layer,
the conductive layer comprises a conductive polymer and a first fluorine-based material, and
the surface energy-tuning layer comprises a second fluorine-based material but does not comprise the conductive polymer.

2. The metal halide perovskite light emitting device of claim 1, wherein the first fluorine-based material and the second fluorine-based material are the same or different from each other.

3. The metal halide perovskite light emitting device of claim 1, wherein the conductive polymer comprises polythiophene, polyaniline, polypyrrole, polystyrene, polyethylenedioxythiophene, polyacetylene, polyphenylene, polyphenylvinylene, polycarbazole, a copolymer comprising two or more different repeating units thereof, a derivative thereof, or a blend of two or more types thereof.

4. The metal halide perovskite light emitting device of claim 1, wherein the conductive polymer comprises a self-doped conductive polymer doped with one or more types of an ionic group and a polymeric acid,
the ionic group comprises an anionic group, and a cationic group disposed to counter the anionic group,
the anionic group is selected from the group consisting of PO₃²⁻, SO₃⁻, COO⁻, I⁻, CH₃COO⁻, and BO₂²⁻,
the cationic group comprises one or more types among a metal ion and an organic ion,
the metal ion is selected from the group consisting of Na⁺, K⁺, Li⁺, Mg⁺², Zn⁺², and Al⁺³, and
the organic ion is selected from the group consisting of H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, and RCHO⁺ (R is CH₃(CH₂)ₙ—; and n is an integer ranging from 0 to 50).

5. The metal halide perovskite light emitting device of claim 1, wherein the first fluorine-based material and the second fluorine-based material are each independently an ionomer represented by the following Formula 1: 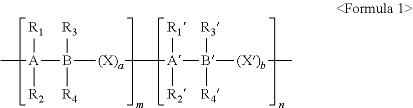
wherein 0<m≦10,000,000, 0≦n<10,000,000, 0≦a≦20, and 0≦b≦20;
A, B, A′, and B′ are each independently selected from the group consisting of C, Si, Ge, Sn, and Pb;
R₁, R₂, R₃, R₄, R₁′, R₂′, R₃′, and R₄′ are each independently selected from the group consisting of hydrogen, a halogen, a nitro group, a substituted or unsubstituted amino group, a cyano group, a substituted or unsubstituted C₁-C₃₀ alkyl group, a substituted or unsubstituted C₁-C₃₀ heteroalkyl group, a substituted or unsubstituted C₁-C₃₀ alkoxy group, a substituted or unsubstituted C₁-C₃₀ heteroalkoxy group, a substituted or unsubstituted C₆-C₃₀ aryl group, a substituted or unsubstituted C₆-C₃₀ arylalkyl group, a substituted or unsubstituted C₆-C₃₀ aryloxy group, a substituted or unsubstituted C₂-C₃₀ heteroaryl group, a substituted or unsubstituted C₂-C₃₀ heteroarylalkyl group, a substituted or unsubstituted C₂-C₃₀ heteroaryloxy group, a substituted or unsubstituted C₅-C₂₀ cycloalkyl group, a substituted or unsubstituted C₂-C₃₀ heterocycloalkyl group, a substituted or unsubstituted C₁-C₃₀ alkylester group, a substituted or unsubstituted C₁-C₃₀ heteroalkylester group, a substituted or unsubstituted C₆-C₃₀ arylester group, and a substituted or unsubstituted C₂-C₃₀ heteroarylester group, provided that at least one of R₁, R₂, R₃, and R₄ is an ionic group, or comprises the ionic group; and
X and X′ are each independently selected from the group consisting of a simple bond, O, S, a substituted or unsubstituted C₁-C₃₀ alkylene group, a substituted or unsubstituted C₁-C₃₀ heteroalkylene group, a substituted or unsubstituted C₆-C₃₀ arylene group, a substituted or unsubstituted C₆-C₃₀ arylalkylene group, a substituted or unsubstituted C₂-C₃₀ heteroarylene group, a substituted or unsubstituted C₂-C₃₀ heteroarylalkylene group, a substituted or unsubstituted C₅-C₂₀ cycloalkylene group, a substituted or unsubstituted C₅-C₃₀ heterocycloalkylene group, a substituted or unsubstituted C₆-C₃₀ arylester group, and a substituted or unsubstituted C₂-C₃₀ heteroarylester group,
provided that, when n is 0, at least one of R₁, R₂, R₃, and R₄ is a hydrophobic functional group containing a halogen element, or comprises the hydrophobic functional group.

6. The metal halide perovskite light emitting device of claim 5, wherein the ionic group comprises an anionic group, and a cationic group disposed to counter the anionic group,
the anionic group is selected from the group consisting of PO₃²⁻, SO₃⁻, COO⁻, I⁻, CH₃COO⁻, and BO₂²⁻,
the cationic group comprises one or more types among a metal ion and an organic ion,
the metal ion is selected from the group consisting of Na⁺, K⁺, Li⁺, Mg+², Zn⁺², and Al⁺³, and
the organic ion is selected from the group consisting of H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, and RCHO⁺ (R is CH₃(CH₂)ₙ—; and n is an integer ranging from 0 to 50).

7. The metal halide perovskite light emitting device of claim 1, wherein the first fluorine-based material and the second fluorine-based material are each independently an ionomer comprising one or more types among repeating units represented by the following Formulas 2 to 13: 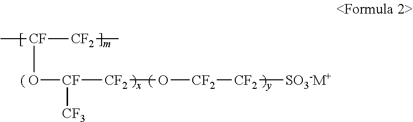
wherein m is an integer ranging from 1 to 10,000,000, x and y are each independently an integer ranging from 0 to 10, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 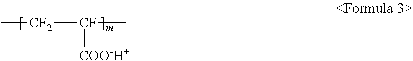
wherein m is an integer ranging from 1 to 10,000,000; 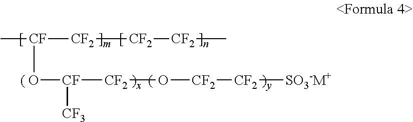
wherein m and n are 0<m≦10,000,000, and 0≦n<10,000,000, respectively, x and y are each independently an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 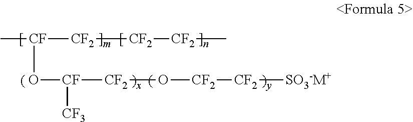
wherein m and n are 0<m≦10,000,000, and 0≦n<10,000,000, respectively, x and y are each independently an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 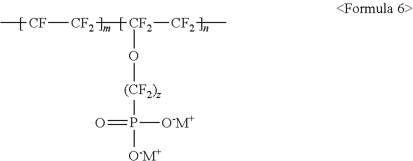
wherein m and n are 0<m≦10,000,000, and 0≦n<10,000,000, respectively, z is an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 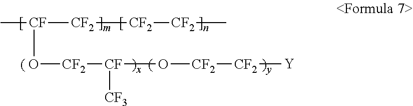
wherein m and n are 0<m≦10,000,000, and 0≦n<10,000,000, respectively, x and y are each independently an integer ranging from 0 to 20, Y is one selected from the group consisting of —COO⁻M⁺, —SO₃⁻NHSO₂CF₃⁺, and —PO₃²⁻(M⁺)₂, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 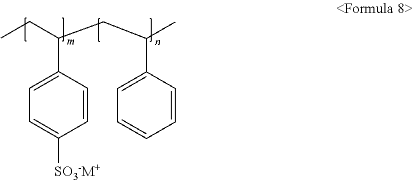
wherein m and n are 0<m≦10,000,000, and 0≦n<10,000,000, respectively, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 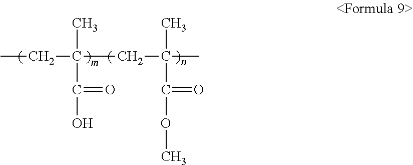
wherein m and n are 0<m≦10,000,000, and 0≦n<10,000,000, respectively; 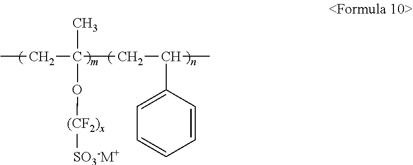
wherein m and n are 0<m≦10,000,000, and 0≦n<10,000,000, respectively, x is an integer ranging from 0 to 20, and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 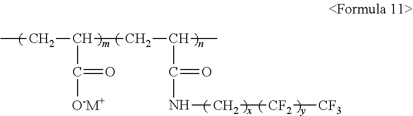
wherein m and n are 0<m≦10,000,000, and 0≦n<10,000,000, respectively, x and y are each independently an integer ranging from 0 to 20, M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50); 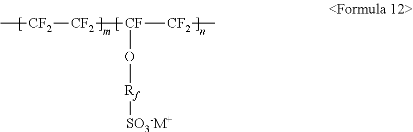
wherein m and n are 0<m≦10,000,000, and 0≦n<10,000,000, respectively, R_{f} is —(CF₂)_{z}⁻ (z is an integer ranging from 1 to 50, provided that z is not 2), —(CF₂CF₂O)_{z}CF₂CF₂— (z is an integer ranging from 1 to 50), or —(CF₂CF₂CF₂O)_{z}CF₂CF₂— (z is an integer ranging from 1 to 50), and M⁺ represents Na⁺, K⁺, Li⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ⁻; and n is an integer ranging from 0 to 50); 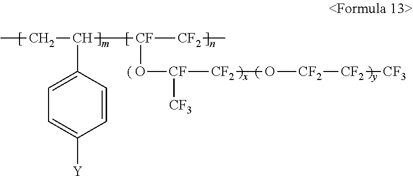
wherein m and n are 0<m≦10,000,000, and 0≦n<10,000,000, respectively, x and y are each independently an integer ranging from 0 to 20, Y is each independently one selected from the group consisting of —SO₃⁻M⁺, —COO⁻M⁺, —SO₃⁻NHSO₂CF₃⁺, and —PO₃²⁻(M⁺)₂, and M⁺ represents Na⁺, K⁺, H⁺, CH₃(CH₂)ₙNH₃⁺ (n is an integer ranging from 0 to 50), NH₄⁺, NH₂⁺, NHSO₂CF₃⁺, CHO⁺, C₂H₅OH⁺, CH₃OH⁺, or RCHO⁺ (R is CH₃(CH₂)ₙ—; and n is an integer ranging from 0 to 50).

8. The metal halide perovskite light emitting device of claim 1, wherein the first fluorine-based material and the second fluorine-based material are each independently a fluorine-based polymer containing a repeating unit represented by one of Formulas 14 to 19: 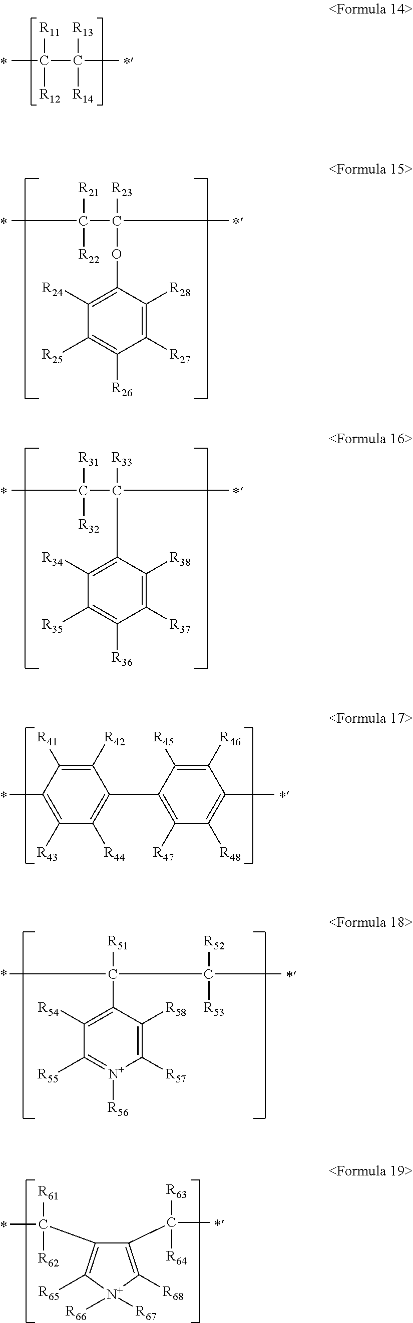
wherein R₁₁ to R₁₄, R₂₁ to R₂₈, R₃₁ to R₃₈, R₄₁ to R₄₈, R₅₁ to R₅₈, and R₆₁ to R₆₈ are each independently selected from the group consisting of hydrogen, —F, a C₁-C₂₀ alkyl group (for example, a methyl group, an ethyl group, a propyl group, a butyl group, a pentyl group, a heptyl group, a hexyl group, and an octyl group), a C₁-C₂₀ alkoxy group (for example, a methoxy group, an ethoxy group, a propoxy group, a butoxy group, and a pentoxy group), a C₁-C₂₀ alkyl group substituted with at least one —F (for example, a methyl group, an ethyl group, a propyl group, a butyl group, a pentyl group, a heptyl group, a hexyl group, and an octyl group, all of which are substituted with at least one —F), a C₁-C₂₀ alkoxy group substituted with at least one —F (for example, a methoxy group, an ethoxy group, a propoxy group, a butoxy group, and a pentoxy group, all of which are substituted with at least one —F), Q₁, —O—(CF₂CF(CF₃)—O)ₙ—(CF₂)ₘ-Q₂ (where n and m are each independently an integer ranging from 0 to 20, provided that the sum of n and m is greater than or equal to 1), and —(OCF₂CF₂)ₓ-Q₃ (where x is an integer ranging from 1 to 20), provided that:
i) at least one of R₁₁ to R₁₄ in Formula 14,
ii) at least one of R₂₁ to R₂₈ in Formula 15,
iii) at least one of R₃₁ to R₃₈ in Formula 16,
iv) at least one of R₄₁ to R₄₈ in Formula 17,
v) at least one of R₅₁ to R₅₈ in Formula 18, and
v) at least one of R₆₁ to R₆₈ in Formula 19 are selected from the group consisting of —F, a C₁-C₂₀ alkyl group substituted with at least one —F, a C₁-C₂₀ alkoxy group substituted with at least one —F, —O—(CF₂CF(CF₃)—O)ₙ—(CF₂)ₘ-Q₂, and —(OCF₂CF₂)ₓ-Q₃.

9. The metal halide perovskite light emitting device of claim 1, wherein the first fluorine-based material and the second fluorine-based material are each independently a fluorinated oligomer represented by the following Formula 20:
X-M^{f}ₙ-M^{h}ₘ-M^{a}ᵣ-G <Formula 20>
wherein X is an end group;
M^{f} represents a unit derived from a fluorinated monomer obtained from a condensation reaction of a perfluoropolyether alcohol, a polyisocyanate, and an isocyanate-reactive non-fluorinated monomer;
M^{h} represents a unit derived from a non-fluorinated monomer;
M^{a} represents a unit containing a silyl group represented by —Si(Y₄)(Y₅)(Y₆);
Y₄, Y₅, and Y₆ each independently represent a substituted or unsubstituted C₁-C₂₀ alkyl group, a substituted or unsubstituted C₆-C₃₀ aryl group, or a hydrolyzable substituent, provided that at least one of Y₄, Y₅, and Y₆ is the hydrolyzable substituent;
G is a monovalent organic group containing a residue of a chain transfer agent;
n is an integer ranging from 1 to 100;
m is an integer ranging from 0 to 100; and
r is an integer ranging from 0 to 100;
provided that the sum of n, m, and r is at least 2.

10. The metal halide perovskite light emitting device of claim 1, wherein the first electrode further comprises an interlayer disposed between the conductive layer and the surface energy-tuning layer,
the interlayer comprises the first fluorine-based material and the second fluorine-based material, and
the first fluorine-based material and the second fluorine-based material are different from each other.

11. The metal halide perovskite light emitting device of claim 10, wherein the first fluorine-based material and the second fluorine-based material included in the interlayer have a concentration gradient formed to decrease in a direction spanning from the surface energy-tuning layer to the conductive layer.

12. The metal halide perovskite light emitting device of claim 1, wherein the conductive layer further comprises at least one additive selected from the group consisting of carbon nanotubes, graphene, reduced graphene oxide, metal nanowires, metal carbon nanodots, semiconductor quantum dots, semiconductor nanowires, and metal nanodots.

13. The metal halide perovskite light emitting device of claim 1, wherein the first electrode further comprises an auxiliary conductive thin film layer disposed on a bottom surface of the conductive layer, and
the auxiliary conductive thin film layer comprises at least one selected from the group consisting of a conductive polymer, metallic carbon nanotubes, graphene, reduced graphene oxide, metal nanowires, a metal grid, carbon nanodots, semiconductor nanowires, and metal nanodots.

14. The metal halide perovskite light emitting device of claim 1, wherein the metal halide perovskite material has compositions of ABX₃, A₂BX₄, ABX₄ or Aₙ₋₁PbₙI₃ₙ₊₁ (n is an integer ranging from 2 to 6), wherein:
A is a monovalent organic cation or a monovalent metal cation,
B is a divalent metal ion, and
X is a monovalent halide ion.

15. The metal halide perovskite light emitting device of claim 14, wherein A is an amidinium-based organic ion, an organic ammonium cation, or a monovalent alkali metal cation,
B is Pb, Mn, Cu, Ga, Ge, In, Al, Sb, Bi, Po, Sn, Eu, Yb, Ni, Co, Fe, Cr, Pd, Cd, Ca, Sr, or a combination thereof, and
X is Cl, Br, I, or a combination thereof.

16. A method of manufacturing a metal halide perovskite light emitting device, the method comprising:
forming a first electrode on a substrate;
forming a light emitting layer comprising a metal halide perovskite material on the first electrode; and
forming a second electrode on the light emitting layer,
wherein the first electrode comprises a conductive layer and a surface energy-tuning layer disposed on the conductive layer,
the conductive layer comprises a conductive polymer and a first fluorine-based material, and
the surface energy-tuning layer comprises a second fluorine-based material, but does not comprise the conductive polymer.

17. The method of claim 16, wherein the forming of the first electrode comprises:
providing a first mixture, which comprises a conductive polymer, a first fluorine-based material, and a first solvent, onto the substrate and then removing at least a portion of the first solvent to form a conductive layer; and
providing a second mixture, which comprises a second fluorine-based material and a second solvent, onto the conductive layer and then removing at least a portion of the second solvent to form a surface energy-tuning layer.

18. The method of claim 16, wherein the first electrode further comprises an interlayer disposed between the conductive layer and the surface energy-tuning layer,
the interlayer comprises the first fluorine-based material and the second fluorine-based material, and
the first fluorine-based material and the second fluorine-based material are different from each other.

19. The method of claim 18, wherein the forming of the first electrode comprises:
providing a first mixture, which comprises a conductive polymer, a first fluorine-based material, and a first solvent, onto the substrate and then removing at least a portion of the first solvent to form a conductive layer; and
providing a second mixture, which comprises a second fluorine-based material and a second solvent, onto the conductive layer and then removing at least a portion of the second solvent to form an interlayer and a surface energy-tuning layer at the same time.

20. The method of claim 19, wherein a first layer comprising the conductive polymer, the first fluorine-based material, the second fluorine-based material, and the second solvent is formed, and a second layer comprising the second fluorine-based material and the second solvent is formed on the first layer when the second mixture is provided onto the conductive layer, and
the interlayer comprising the conductive polymer, the first fluorine-based material, and the second fluorine-based material, and the surface energy-tuning layer comprising the second fluorine-based material but not comprising the conductive polymer are formed at the same time by removing the second solvent.
